(19) United States
(12) Patent Application Publication
(10) Pub. No.: US 2026/0052825 A1
(43) Pub. Date: Feb. 19, 2026

(54) DISPLAY APPARATUS AND VEHICLE

(71) Applicant: LG Display Co., Ltd., Seoul (KR)

(72) Inventor: Sangmoo SONG, Paju-si (KR)

(73) Assignee: LG Display Co., Ltd., Seoul (KR)

(21) Appl. No.: 19/242,797

(22) Filed: Jun. 18, 2025

(30) Foreign Application Priority Data
Aug. 19, 2024 (KR) 10-2024-0110525

(51) Int. Cl. H10H 29/855; B60K 35/22; H10H 29/34; H10K 59/80

(52) U.S. Cl. CPC H10H 29/8552; B60K 35/22; H10H 29/34; H10K 59/879; H10K 59/8792; B60K 2360/1526

(57) ABSTRACT

A display apparatus and a vehicle including the display apparatus are discussed. The display apparatus can include a first pixel group having a plurality of pixels, a first microlens corresponding to each of the plurality of pixels of the first pixel group, and a first light-shielding member corresponding to each of the plurality of pixels of the first pixel group. The first light-shielding member is disposed at at least one of a first side and a second side of the first microlens in a specific direction.

### CROSS-REFERENCE TO RELATED APPLICATION

The present application claims priority to Korean Patent Application No. 10-2024-0110525, filed in the Republic of Korea on Aug. 19, 2024, the entire contents of which is hereby expressly incorporated by reference, as if fully set forth herein into the present application.

### BACKGROUND

### Technical Field

The present specification relates to a display apparatus and a vehicle.

### Discussion of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a high contrast ratio, and is lighter and thinner and has less power consumption than the LCD because it does not require a separate backlight. In addition, there is an advantage in that the OLED display apparatus can drive at a low voltage, have a fast response time, and especially have the inexpensive manufacturing cost.

The OLED display apparatus can also be applied to display apparatuses mounted on vehicles.

The description provided in the background section should not be assumed to be prior art merely because it is mentioned in or associated with the background section. The background section can include information that describes one or more aspects of the subject technology.

### SUMMARY OF THE DISCLOSURE

The inventor of the present application found that, among display apparatuses installed on a vehicle, display apparatuses in front of a driver's seat and a front passenger's seat need to limit a viewing angle of a driver according to driving situations of the driver. The display apparatus needs to limit a viewing angle according to a user's needs for privacy and information protection.

The present disclosure is directed to providing a display apparatus having a design with improved aesthetic feeling.

The present disclosure is also directed to providing a display apparatus in which it is possible to easily control a path of light emitted from a light-emitting part.

The present disclosure is also directed to providing a display apparatus in which it is possible to reduce, suppress or prevent degradation of luminance of a displayed screen.

The present disclosure is also directed to providing a display apparatus in which it is possible to reduce, suppress or prevent distortion of a screen.

The present disclosure is also directed to providing a display apparatus in which it is possible to reduce, suppress or prevent degradation of luminance of the display apparatus, thereby minimizing a reduction in luminous efficiency.

Objects of the present disclosure are not limited to the above-described objects, and other technical objects can be inferred from the following embodiments.

According to one example embodiment of the present disclosure, there is provided a display apparatus including a first pixel group including a plurality of pixels, a first microlens corresponding to each of the plurality of pixels of the first pixel group, and a first light-shielding member corresponding to each of the plurality of pixels of the first pixel group, wherein the first light-shielding member is disposed at at least one of one side (e.g., first side) and the other side (e.g., second side) of the first microlens in a first direction.

According to another example embodiment of the present disclosure, there is provided a display apparatus including a first pixel group including a plurality of pixels, a third pixel group including a plurality of pixels, a first microlens corresponding to each of the plurality of pixels of the first pixel group, a third microlens corresponding to each of the plurality of pixels of the third pixel group, a first light-shielding member corresponding to each of the plurality of pixels of the first pixel group, and a third light-shielding member corresponding to each of the plurality of pixels of the third pixel group, wherein the first light-shielding member is disposed at one side (e.g., first side) of the first microlens in a first direction, and the third light-shielding member is disposed at the other side (e.g., second side) of the third microlens in the first direction.

Detailed matters of other embodiments are included in the detailed description and accompanying drawings.

According to the example embodiments of the present disclosure, it is possible to provide the display apparatus with improved aesthetic feeling.

According to the example embodiments of the present disclosure, it is possible to easily control the path of light emitted from the light-emitting part.

According to the example embodiments of the present disclosure, it is possible to reduce, suppress or prevent the degradation of luminance of the displayed screen.

According to the example embodiments of the present disclosure, it is possible to reduce, suppress or prevent the distortion of the screen.

According to the example embodiments of the present disclosure, it is possible to reduce, suppress or prevent the degradation of luminance of the display apparatus, thereby suppressing or preventing the reduction in luminous efficiency.

According to the example embodiments of the present disclosure, it is possible to reduce, suppress or prevent the degradation of luminance of the display apparatus, thereby reducing power consumption.

However, effects obtainable from the present disclosure are not limited to the above-described effects, and other effects that are not mentioned will be able to be clearly understood by those skilled in the art to which the present disclosure pertains based on the following description.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display apparatus according to one example embodiment of the present disclosure.

FIG. 2 is an enlarged view of area Q1 in FIG. 1.

FIG. 3 is a view illustrating only a display panel of FIG. 2.

FIG. 4 is a plan view illustrating a pixel arrangement of a display panel according to one example embodiment of the present disclosure.

FIG. 5 is a cross-sectional view along line D-D′ in FIG. 4.

FIG. 6 is a cross-sectional view along line E-E′ in FIG. 4.

FIG. 7 is a cross-sectional view along line F-F′ in FIG. 4.

FIG. 8 is a cross-sectional view of a touch part of FIG. 5 taken at a different angle.

FIG. 9 is a schematic view illustrating a path of light in FIG. 5.

FIG. 10 is a schematic view illustrating a path of light in FIG. 6.

FIG. 11 is a schematic view illustrating a path of light in FIG. 7.

FIG. 12 is a cross-sectional view along line A-A′ in FIG. 1.

FIG. 13 is a cross-sectional view along line B-B′ in FIG. 3.

FIG. 14 is a cross-sectional view along line C-C′ in FIG. 3.

FIG. 15 is a plan view illustrating a pixel arrangement of a display panel according to another example embodiment of the present disclosure.

FIG. 16 is a plan view illustrating a pixel arrangement of a display panel according to still another example embodiment of the present disclosure.

FIG. 17 is a plan view illustrating a pixel arrangement of a display panel according to yet another example embodiment of the present disclosure.

FIGS. 18 to 20 are cross-sectional views of a display panel of a display apparatus according to yet another example embodiment of the present disclosure.

FIG. 21 is a plan view of a display apparatus according to yet another example embodiment of the present disclosure.

FIG. 22 is an enlarged view of area Q2 in FIG. 21.

FIG. 23 is a cross-sectional view along line K-K′ in FIG. 22.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Hereinafter, embodiments of the present disclosure will be described with reference to the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the disclosure and can be thus different from those used in actual products. In the disclosure, when a first component (or an area, a layer, a portion, etc.) is described as “on,” “connected,” or “coupled to” a second component, it means that the first component can be directly on, connected/coupled to the second component or a third component can be disposed therebetween.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments can be provided so that this disclosure can be sufficiently thorough and complete to assist those skilled in the art to fully understand the scope of the present disclosure. Further, the present disclosure is only defined by scopes of claims.

The shapes (e.g., sizes, lengths, widths, heights, thicknesses, locations, radii, diameters, and areas), ratios, angles, numbers, and the like, which are illustrated in the drawings to describe various example embodiments of the present disclosure are merely given by way of example. Therefore, the present disclosure is not limited to the illustrations in the drawings. Any implementation described herein as an “example” is not necessarily to be construed as preferred or advantageous over other implementations.

The same reference numerals indicate the same components. In addition, in the drawings, thicknesses, proportions, and dimensions of components are exaggerated for effective description of technical contents. The term “and/or” includes all one or more combinations that can be defined by the associated configurations.

The word “example” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “can” encompasses all the meanings of the term “may” and vice versa. In construing an element, the element is construed as including an error range or tolerance range although there is no explicit description of such an error or tolerance range. Terms such as first and second “A,” “B,” “(a),” and “(b),” can be used to describe various components, but the components are not limited by the terms. The terms are used only for the purpose of distinguishing one component from another. For example, a first component can be referred to as a second component, and similarly, the second component can also be referred to as the first component without departing from the scopes of the embodiments. The singular includes the plural unless the context clearly dictates otherwise.

In describing a time relationship, for example, when the temporal order is described as, for example, “after,” “subsequent,” “next,” and “before,” a case which is not continuous can be included unless a more limiting term, such as “just,”“immediate(ly),”or “direct(ly)”is used.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance.

Features of various example embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example, consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Now, various embodiments of the present disclosure will be discussed referring to the drawings. All the components of each display apparatus according to all embodiments of the present disclosure are operatively coupled and configured.

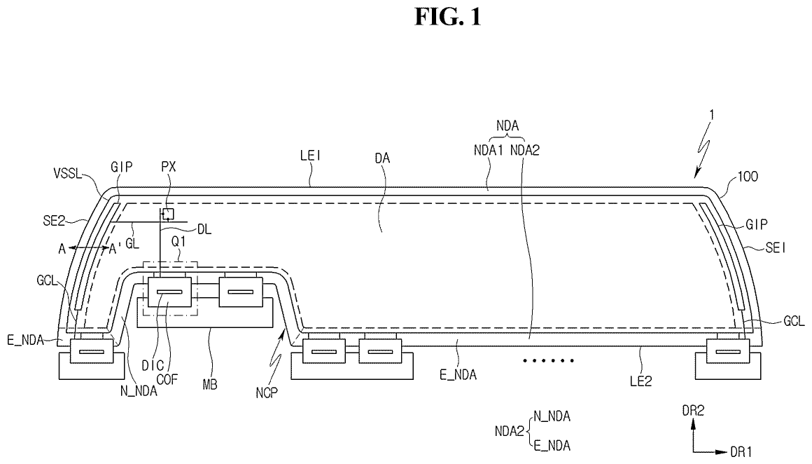

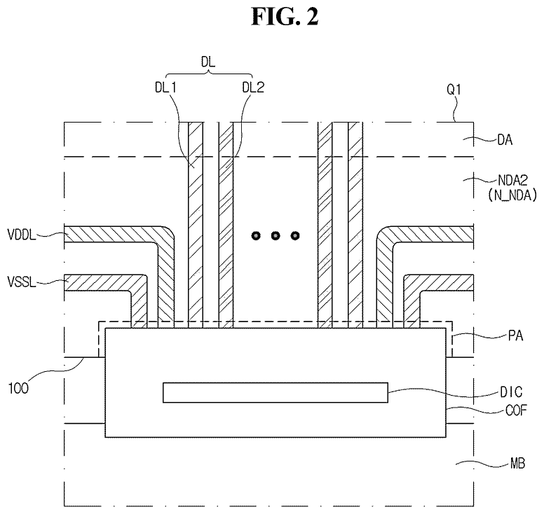

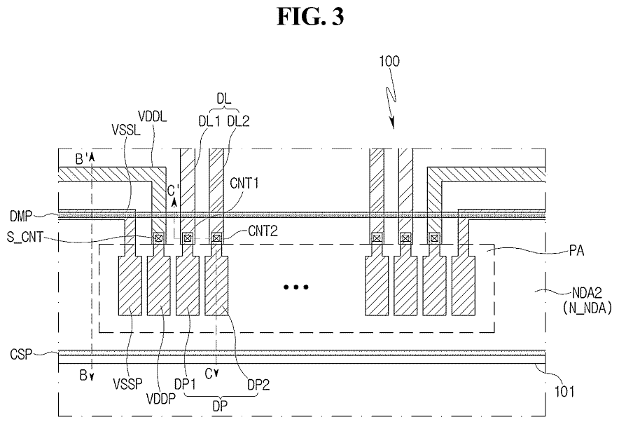

FIG. 1 is a plan view of a display apparatus according to one example embodiment. FIG. 2 is an enlarged view of area Q1 in FIG. 1. FIG. 3 is a view illustrating a display panel of FIG. 2.

Particularly, FIG. 3 is a view of FIG. 2 from which a flexible film COF, a main board MB, and a drive IC DIC are omitted except for the display panel 100. In FIG. 3, for convenience of description, ratios between components are adjusted.

Referring to FIGS. 1 to 3, a display apparatus 1 can be an apparatus including both a display function for displaying an image and a touch sensing function for sensing a user's touch, but is not limited thereto. For example, the display apparatus 1 can include only one of the display function of displaying an image and the touch sensing function of sensing a user's touch.

As an example, the display apparatus 1 can be an electroluminescent display apparatus or a micro light-emitting diode display apparatus that includes a touch sensor, without being limited thereto. The electroluminescent display apparatus including the touch sensor can be an organic light-emitting diode (OLED) display apparatus, a quantum-dot light-emitting diode display apparatus, or an inorganic light-emitting diode display apparatus, without being limited thereto.

The display apparatus 1 according to the present embodiment can be a vehicle display apparatus, but is not limited thereto. For example, the description of the display apparatus 1 can be applied without limitation to the type of the apparatus as long as a display apparatus is an apparatus including a display function.

When the display apparatus 1 according to the present embodiment is a vehicle display apparatus, the display apparatus 1 can include a function of manipulating at least some of various functions of a vehicle, a function of displaying various pieces of information about the vehicle, and the like, without being limited thereto. As an example, even when the display apparatus 1 according to the present embodiment is a vehicle display apparatus, the display apparatus 1 can include not include a function relating to the vehicle, without being limited thereto.

When the display apparatus 1 according to the present embodiment is a vehicle display apparatus, as an example, the display apparatus 1 can be disposed on a dashboard of a vehicle. The display apparatus 1 can be disposed across a driver's seat and a front passenger's seat that are disposed at front seats of a vehicle, but is not limited thereto. As an example, the display apparatus 1 can be disposed to correspond to only one of the driver's seat and a front passenger's seat. As an example, the display apparatus 1 can be disposed at any location other than the dashboard of the vehicle, without being limited thereto.

Both a driver DRIVER sitting on the driver's seat and a passenger CO-DRIVER sitting on the front passenger's seat can use the display apparatus 1. The display apparatus 1 can provide different images to the driver DRIVER sitting on the driver's seat and the passenger CO-DRIVER sitting on the front passenger's seat. However, the embodiments of the present disclosure are not limited thereto, and the display apparatus 1 can provide the same image to both the driver DRIVER sitting on the driver's seat and the passenger CO-DRIVER sitting on the front passenger's seat.

The display apparatus 1 can include a display panel 100. The display panel 100 can include the display area DA and the non-display area NDA.

The display area DA can be an area in which light is emitted to the outside to display a screen. The display area DA can further include a function of sensing a user's touch, without being limited thereto. In this case, the display area DA can correspond to a touch sensing area, but is not limited thereto. As an example, the touch sensing area can overlap only a portion of the display area DA, or can overlap the entirety of the display area DA. As an example, the touch sensing area can be greater than, equal to or smaller than the display area DA.

The display area DA can correspond to the shape of the display panel 100, or can be different from the shape of the display panel 100, but is not limited thereto.

The display panel 100 can include a plurality of pixels PX. The plurality of pixels PX can be disposed in the display area DA. The plurality of pixels PX can be repeatedly disposed, for example, in a first direction DR1 and a second direction DR2, or in a direction between the first direction DR1 and the second direction DR2, without being limited thereto.

The non-display area NDA can be an area in which light is not emitted to the outside so as not to display a screen. The non-display area NDA can be located around the display area DA. The non-display area NDA can partially or fully surround the display area DA, but the embodiments of the present disclosure are not limited thereto. A bezel area of the display apparatus 1 can be defined by the non-display area NDA, but the embodiments of the present disclosure are not limited thereto. As an example, at least a portion or the entirety of the non-display area NDA can be invisible from a front side of the display panel 100, for example, be being bent toward a rear side of the display panel 100, without being limited thereto. As an example, the non-display area NDA can be flat.

The display panel 100 can be a rigid display panel, but is not limited thereto. The display panel 100 can be a flexible display panel of which shape can be deformed, such as a foldable, bendable, rollable, or stretchable display panel.

The display panel 100 can include a first long edge LE1, a second long edge LE2, a first short edge SE1, and a second short edge SE2 that form an edge of the display panel 100. Embodiments are not limited thereto. As an example, the display panel 100 can include three or more sides of the same size or different sizes. As an example, the display panel 100 can have a circular shape, a square shape, an oval shape, a triangle shape, a rectangular shape, a polygonal shape, etc., without being limited thereto.

As an example, the first long edge LE1 and the second long edge LE2 can extend in a first direction DR1, and the first short edge SE1 and the second short edge SE2 can extend in a direction between the first direction DR1 and a second direction DR2 or in the second direction DR2, without being limited thereto. The first long edge LE1 and the second long edge LE2 can have both ends connected through the first short edge SE1 and the second short edge SE2.

The first long edge LE1 can be disposed at one side of the second long edge LE2 in the second direction DR2. The first long edge LE1 and the second long edge LE2 can extend in parallel, but are not limited thereto.

As an example, a length of the first long edge LE1 can be shorter than a length of the second long edge LE2. Accordingly, the first short edge SE1 and the second short edge SE2 can extend in an intersecting direction, but are not limited thereto. As an example, the length of the first long edge LE1 can be greater than or equal to the length of the second long edge LE2. As an example, the first short edge SE1 and the second short edge SE2 can extend in parallel, without being limited thereto.

The first direction DR1 and the second direction DR2 can be directions intersecting each other. The first direction DR1 and the second direction DR2 can be orthogonal, but are not limited thereto. The first direction DR1 and the second direction DR2 are provided to clarify the description of the invention, the first direction DR1 and the second direction DR2 are relative, and the embodiments of the present disclosure are not limited thereto.

In a plan view, the first long edge LE1 can be disposed above the display area DA, and the second long edge LE2 can be disposed under the display area DA.

In a plan view, the first short edge SE1 can be disposed at the right side of the display area DA, and the second short edge SE2 can be disposed at the left side of the display area DA.

As an example, the display panel 100 can include a curved notch NCP, without being limited thereto. The notch NCP can be formed at the second long edge LE2, but is not limited thereto. For example, the second long edge LE2 can entirely extend in the first direction DR1, but can include the notch NCP that is curved toward the first long edge LE1. As an example, the notch NCP can be formed at any one or more edges of the display panel 100, or can be omitted depending on the design, without being limited thereto. As an example, the display panel 100 can include one or more curved notches NCP formed on one edge or more edges, without being limited thereto.

Since the notch NCP is disposed, components, such as a handle of a driver's seat, can be disposed on the corresponding portion to increase or maximize the display area DA capable of displaying the screen, thereby improving a user's convenience and improving aesthetic feeling. Embodiments are not limited thereto. As an example, even if the notch NCP is disposed, no component can be disposed on the corresponding portion, without being limited thereto.

The non-display area NDA can include a first non-display area NDA1 disposed along the first long edge LE1, the first short edge SE1, and the second short edge SE2, and a second non-display area NDA2 disposed along the second long edge LE2. The second non-display area NDA2 can be disposed along the second long edge LE2 including the curved notch NCP.

The first non-display area NDA1 can be disposed at one side and the other side of the display area DA in the first direction DR1 and disposed at one side of the display area DA in the second direction DR2.

The second non-display area NDA2 can include a notch non-display area N_NDA disposed around the notch NCP, and an extension non-display area E_NDA disposed around the notch non-display area N_NDA.

The extension non-display area E_NDA can extend from the notch non-display area N_NDA in the first direction DR1. The extension non-display area E_NDA can be disposed between the notch non-display area N_NDA and the first non-display area NDA1. The extension non-display area E_NDA can connect the notch non-display area N_NDA to the first non-display area NDA1.

The display apparatus 1 can further include a pad area PA, a gate driving unit GIP, a main board MB, a flexible film COF, a drive IC DIC, a gate line GL, a gate control line GCL, a data line DL, a low-potential voltage line VSSL, and/or a high-potential voltage line VDDL. Embodiments are not limited thereto. As an example, at least one or more of the above-mentioned components can be omitted, and/or one or more additional components can be further included.

The pad area PA can overlap the flexible film COF. The pad area PA can be attached to the flexible film COF. For example, the display panel 100 and the flexible film COF can be attached through the pad area PA.

The pad area PA can be disposed in the non-display area NDA. The pad area PA can be disposed in the second non-display area NDA2. The pad area PA can be disposed in each of the notch non-display area N_NDA and the extension non-display area E_NDA.

The pad area PA can include a plurality of pads. The pad area PA can include a low-potential voltage pad VSSP, a high-potential voltage pad VDDP, a first data pad DP1, and a second data pad DP2. The low-potential voltage pad VSSP, the high-potential voltage pad VDDP, the first data pad DP1, and the second data pad DP2 can be disposed in the pad area PA.

However, the embodiments of the present disclosure are not limited thereto, and the pad area PA disposed in an area that overlaps the flexible films COF disposed at both ends among the flexible films COF disposed along the non-display area NDA can further include a gate control pad. Embodiments are not limited thereto. As an example, the pad area PA disposed in an area that overlaps a flexible films COF other than the flexible films COF disposed at both ends among the flexible films COF disposed along the non-display area NDA can further include a gate control pad, without being limited thereto. As an example, the pad area PA disposed in an area that overlaps the flexible films COF disposed at both ends among the flexible films COF disposed along the non-display area NDA can only include the gate control pad, without being limited thereto.

The gate driving unit GIP can be disposed in the non-display area NDA. The gate driving unit GIP can be disposed at at least one of one side and the other side of the display area DA in the first direction DR1, but is not limited thereto. In a plan view, the gate driving unit GIP can be disposed at the left side and the other side of the display area DA. As an example, the gate driving unit may not be disposed on the display panel. As an example, the gate driving unit can be separately disposed in a separate panel and connected to the display panel 100, for example, in a tape automated bonding (TAB) method, a chip on glass (COG) method, a chip on panel (COP) method, or a chip on film (COF) method, without being limited thereto.

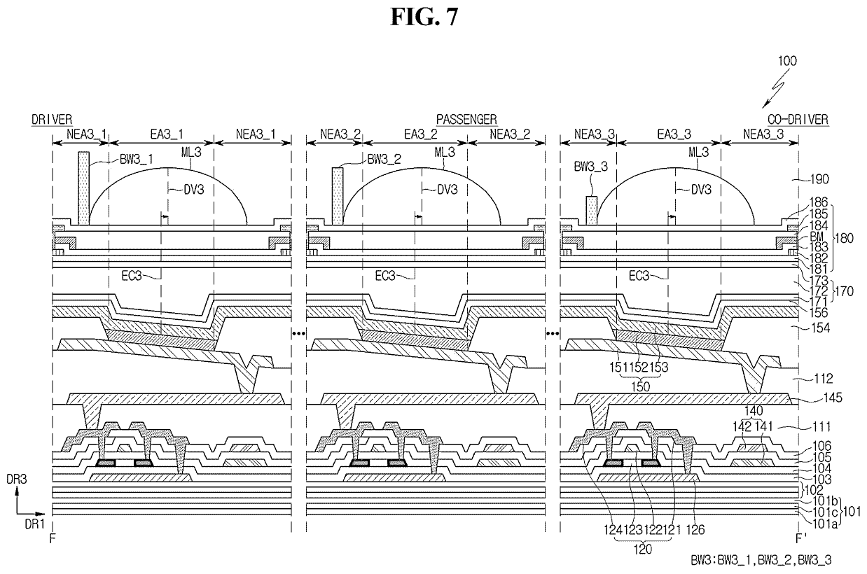

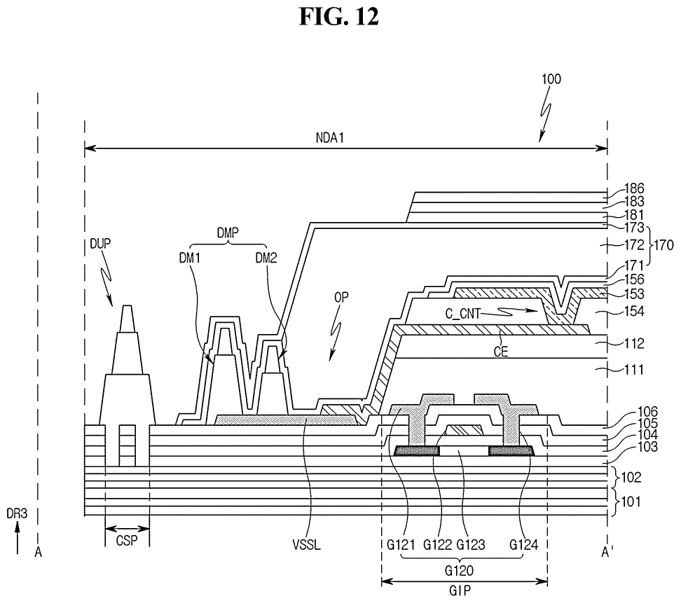

The gate driving unit GIP can include a plurality of transistors G120 (see FIG. 12). The transistors G120 (see FIG. 7) disposed in the gate driving unit GIP can be connected to a pixel PX through the gate line GL. The gate driving unit GIP can apply a gate signal to each pixel PX through the gate line GL.

The gate driving unit GIP can receive a gate control signal from the drive IC DIC through the gate control line GCL. The gate driving unit GIP can generate a scan signal and a light-emitting signal (or a light-emitting control signal) based on the gate control signal.

The gate driving unit GIP can include a scan driver and/or an light-emitting signal driver. The scan driver can generate a scan signal in a row-sequential manner and supply the scan signal to the scan lines in order to drive one or more scan lines connected to each pixel PX row. The light-emitting signal driver can generate an light-emitting signal in a row-sequential manner and supply the light-emitting signal to light-emitting signal lines in order to drive one or more light-emitting signal lines connected to each pixel PX row.

The main board MB can be connected to the display panel 100 through the flexible film COF. The main board MB can be electrically connected to the pixel PX of the display area DA through the flexible film COF. The main board MB can be electrically connected to the flexible film COF. The main board MB and the flexible film COF can be electrically connected through the plurality of pads VSSP, VDDP, and DP.

The main board MB can have various types of components for supplying various signals, such as a gate control signal, a driving signal, a data signal, etc., to the drive IC DIC. The main board MB can be a printed circuit board, but is not limited thereto.

The main board MB can be connected to the display panel 100 through the flexible film COF in the second non-display area NDA2. The main board MB can be provided as a plurality of main boards along the second non-display area NDA2, but is not limited thereto. The number of main boards MB can vary according to a design.

At least one of the main boards MB can be disposed around the notch NCP and connected to the display panel 100 through the flexible film COF in the notch non-display area N_NDA, without being limited thereto. As an example, the main board MB can be connected to the display panel 100 through the flexible film COF in the first non-display area NDA1. As an example, the main boards MB may not be disposed around the notch NCP, without being limited thereto.

The flexible film COF can be connected to the display panel 100 and the main board MB. The flexible film COF can be attached to each of the display panel 100 and the main board MB and electrically connected to each of the display panel 100 and the main board MB. For example, the display panel 100 and the main board MB can be electrically connected through the flexible film COF. The flexible film COF can be provided as a plurality of flexible films, but is not limited thereto.

The flexible film COF can be attached to the display panel 100 in the second non-display area NDA2. The flexible film COF can be repeatedly disposed along the second non-display area NDA2. The flexible film COF can be attached to the display panel 100 across the notch non-display area N_NDA and the extension non-display area E_NDA.

A single main board MB can be electrically connected to the display panel 100 through at least one flexible film COF. For example, the main boards MB disposed at both ends among the plurality of main boards MB disposed along the second non-display area NDA2 can be electrically connected to the display panel 100 through one flexible film COF, and the remaining main boards MB can be electrically connected to the display panel 100 through two flexible films COF, without being limited thereto.

The flexible film COF can be electrically connected to the pad area PA. Accordingly, the flexible film COF can supply gate control signals, driving signals, power voltages, data voltages, and the like to the plurality of pixels PX and the gate driving unit GIP that are disposed in the display area DA.

The flexible film COF can be a flexible insulating film. The flexible film COF can include, for example, polycarbonate, polyethylene terephthalate, polyimide, polyamide, polyester, polyacrylate, polymethyl methacrylate, etc., but is not limited thereto.

The drive IC DIC can be mounted on the flexible film COF. The drive IC DIC can be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC can drive the display apparatus 1. The drive IC DIC can process data signals for displaying an image, various driving signals for processing the data signals, etc. The drive IC DIC can include a gate driver IC, a data driver IC, etc.

The gate line GL can be extended from the gate driving unit GIP and connected to the pixel PX. The gate line GL can electrically connect the gate driving unit GIP and the pixel PX. The gate line GL can apply the gate signal from the gate driving unit GIP to each pixel PX.

The gate control line GCL can be disposed in the non-display area NDA. The gate control line GCL can extend from the pad area PA to the gate driving unit GIP and can be electrically connected to the gate driving unit GIP.

The gate control line GCL can apply the gate control signal to the gate driving unit GIP. The gate control signal can be transmitted from the main board MB or the drive IC DIC. The gate control line GCL can electrically connect the gate driving unit GIP to the main board MB or the drive IC DIC.

The gate control line GCL can be electrically connected to the flexible film COF disposed at both ends among the plurality of flexible films COF connected to the display panel 100 along the second non-display area NDA2, without being limited thereto. The gate control line GCL can be disposed at an outermost edge among a plurality of lines connected to one flexible film COF, but is not limited thereto. As an example, the gate control line GCL can be electrically connected to a flexible film COF other than the flexible film COF disposed at both ends among the plurality of flexible films COF connected to the display panel 100 along the second non-display area NDA2, without being limited thereto.

The data line DL can extend from the pad area PA and can be connected to the pixel PX of the display area DA. The data line DL can apply the data signal to each pixel PX. The data signal can be applied from the main board MB or the drive IC DIC. The data line DL can electrically connect the pixel PX to the main board MB or the drive IC DIC.

The data line DL can include a first data line DL1 and a second data line DL2. The data line DL can be connected to the data pads DP1 and DP2. The first data line DL1 can be electrically connected in contact with the first data pad DP1 through a first data contact hole CNT1. The second data line DL2 can be electrically connected in contact with the second data pad DP2 through a second data contact hole CNT2. Embodiments are not limited thereto. As an example, the data line DL can be directly connected with the data pad DP without any contact hole, without being limited thereto. As an example, the data line DL and the data pad DP can be formed integrally, but are not limited thereto.

The low-potential voltage line VSSL can be disposed in the non-display area NDA to surround the display area DA. The low-potential voltage line VSSL can be disposed in the non-display area NDA with the display area DA and the gate driving unit GIP interposed therebetween. For example, the gate driving unit GIP can be disposed between the display area DA and the low-potential voltage line VSSL, without being limited thereto.

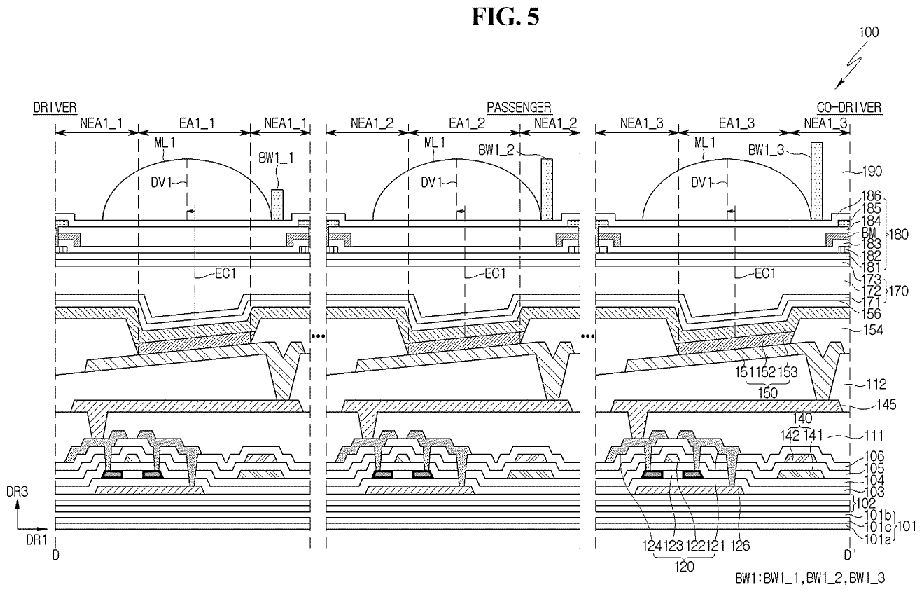

The low-potential voltage line VSSL can apply a low-potential voltage to the pixel PX. The low-potential voltage line VSSL can be electrically connected to the cathode electrode 153 (see FIG. 5) of the pixel PX to apply a low-potential voltage.

The low-potential voltage line VSSL can be connected to the pad area PA. The low-potential voltage line VSSL can be physically connected to the low-potential voltage pad VSSP and electrically connected to the low-potential voltage pad VSSP. The low-potential voltage line VSSL and the low-potential voltage pad VSSP can be formed integrally, but are not limited thereto.

The high-potential voltage line VDDL can be disposed between the display area DA and the low-potential voltage line VSSL, without being limited thereto. The high-potential voltage line VDDL can apply a high-potential voltage to the pixel PX. The high-potential voltage line VDDL can be electrically connected to the anode electrode 151 (see FIG. 5) of the pixel PX to apply a high-potential voltage.

The high-potential voltage line VDDL can be connected to the pad area PA. The high-potential voltage line VDDL can be physically connected to the high-potential voltage pad VDDP and electrically connected to the high-potential voltage pad VDDP. The high-potential voltage line VDDL can come into contact with the high-potential voltage pad VDDP by a high-potential contact hole S_CNT.

However, the embodiments of the present disclosure are not limited thereto, and the high-potential voltage line VDDL and the high-potential voltage pad VDDP can be formed integrally. For example, the high-potential voltage line VDDL can be formed of the same material and the same conductive layer as the high-potential voltage pad VDDP, and the high-potential voltage line VDDL and the high-potential voltage pad VDDP are formed together by the same mask process.

The display apparatus 1 can further include a dam part DMP. The dam part DMP can be disposed in the non-display area NDA. The dam part DMP can be disposed to surround the display area DA, but is not limited thereto. At least a part of the dam part DMP can be disposed to overlap the low-potential voltage line VSSL, without being limited thereto. The dam part DMP can be disposed between the display area DA and the pad area PA in the second non-display area NDA2.

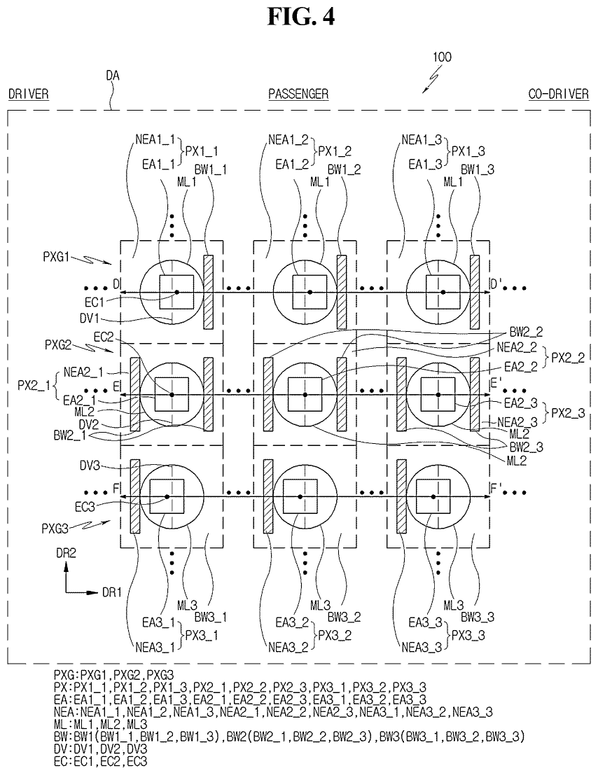

FIG. 4 is an enlarged view illustrating a pixel arrangement of a display panel according to one example embodiment. Particularly, FIG. 4 is a schematic view illustrating a flat surface structure of the display area DA in which the pixels PX are disposed, and the flat surface shape of the display area DA can be substantially the same as the flat surface shape of FIG. 1.

Referring to FIG. 4, the display panel 100 can include a plurality of pixel groups PXG (PXG1, PXG2, and PXG3). The pixel group PXG can include a first pixel group PXG1, a second pixel group PXG2, and a third pixel group PXG3. The first pixel group PXG1, the second pixel group PXG2, and the third pixel group PXG3 can be disposed in the display area DA. Embodiments are not limited thereto. As an example, the display panel 100 can include two pixel groups, four pixel groups or more pixel groups, without being limited thereto.

Each of the pixel groups PXG1, PXG2, and PXG3 can include a plurality of pixels PX. The pixels PX disposed in each pixel group PXG1, PXG2, or PXG3 can be disposed in the first direction DR1, without being limited thereto. As an example, the pixels PX disposed in each pixel group PXG1, PXG2, or PXG3 can be disposed in a direction intersecting the first direction DR1. As an example, the pixels PX disposed in each pixel group PXG1, PXG2, or PXG3 can be disposed in a matrix, without being limited thereto.

The first pixel group PXG1, the second pixel group PXG2, and the third pixel group PXG3 can be alternately and repeatedly disposed in the second direction DR2.

For example, the first pixel group PXG1 can include a 1_1 pixel PX1_1, a 1_2 pixel PX1_2, a 1_3 pixel PX1_3, etc. that are disposed along the first direction DR1. The second pixel group PXG2 can include a 2_1 pixel PX2_1, a 2_2 pixel PX2_2, a 2_3 pixel PX2_3, etc. that are disposed along the first direction DR1. The third pixel group PXG3 can include a 3_1 pixel PX3_1, a 3_2 pixel PX3_2, a 3_3 pixel PX3_3, etc. that are disposed along the first direction DR1.

The 1_1 pixel PX1_1, the 1_2 pixel PX1_2, and the 1_3 pixel PX1_3 are some of the pixels PX included in the first pixel group PXG1, the 2_1 pixel PX2_1, the 2_2 pixel PX2_2, and the 2_3 pixel PX2_3 are some of the pixels PX included in the second pixel group PXG2, and the 3_1 pixel PX3_1, the 3_2 pixel PX3_2, and the 3_3 pixel PX3_3 are some of the pixels PX included in the third pixel group PXG3.

Each pixel PX can emit light of a different color. For example, the pixel PX can emit red (R) light, green (G) light, blue (B) light, or white (W) light, or can emit light of other color. As an example, at least some of the pixels PXs can emit light of the same color.

Each pixel PX can include an light-emitting area EA that emits light and a non-light-emitting area disposed around the light-emitting area EA. As an example, each pixel can include one or more light-emitting areas EA that emit light and one or more non-light-emitting areas disposed around the light-emitting areas EA, without being limited thereto.

The 1_1 pixel PX1_1 can include a 1_1 light-emitting area EA1_1, and a 1_1 non-light-emitting area NEA1_1 disposed around the 1_1 light-emitting area EA1_1.

The 1_2 pixel PX1_2 can include a 1_2 light-emitting area EA1_2, and a 1_2 non-light-emitting area NEA1_2 disposed around the 1_2 light-emitting area EA1_2.

The 1_3 pixel PX1_3 can include a 1_3 light-emitting area EA1_3, and a 1_3 non-light-emitting area NEA1_3 disposed around the 1_3 light-emitting area EA1_3.

The 2_1 pixel PX2_1 can include a 2_1 light-emitting area EA2_1, and a 2_1 non-light-emitting area NEA2_1 disposed around the 2_1 light-emitting area EA2_1.

The 2_2 pixel PX2_2 can include a 2_2 light-emitting area EA2_2, and a 2_2 non-light-emitting area NEA2_2 disposed around the 2_2 light-emitting area EA2_2.

The 2_3 pixel PX2_3 can include a 2_3 light-emitting area EA2_3, and a 2_3 non-light-emitting area NEA2_3 disposed around the 2_3 light-emitting area EA2_3.

The 3_1 pixel PX3_1 can include a 3_1 light-emitting area EA3_1, and a 3_1 non-light-emitting area NEA3_1 disposed around the 3_1 light-emitting area EA3_1.

The 3_2 pixel PX3_2 can include a 3_2 light-emitting area EA3_2, and a 3_2 non-light-emitting area NEA3_2 disposed around the 3_2 light-emitting area EA3_2.

The 3_3 pixel PX3_3 can include a 3_3 light-emitting area EA3_3, and a 3_3 non-light-emitting area NEA3_3 disposed around the 3_3 light-emitting area EA3_3.

A microlens ML (ML1, ML2, or ML3) can be disposed on each pixel group PXG1, PXG2, or PXG3. A first microlens ML1 can be disposed on the pixels PX of the first pixel group PXG1, a second microlens ML2 can be arranged on the pixels PX of the second pixel group PXG2, and a third microlens ML3 can be disposed on the pixels PX of the third pixel group PXG3.

Each microlens ML1, ML2, or ML3 can adjust a path of light emitted from each pixel PX. Each microlens ML1, ML2, or ML3 can adjust a path of light emitted from the pixels PX of each pixel group PXG1, PXG2, or PXG3 in a different direction.

For example, the first microlens ML1 can adjust the light emitted from the pixels PX of the first pixel group PXG1 to travel toward the other side in the first direction DR1 in a plan view, the second microlens ML2 can collect the light emitted from the pixel PX of the second pixel group PXG2 and adjust the light to travel in a thickness direction, and the third microlens ML3 can adjust the light emitted from the pixels PX of the third pixel group PXG3 to travel toward one side in the first direction DR1 in a plan view.

Accordingly, each pixel group PXG1, PXG2, or PXG3 can display a different image and video, and the display apparatus 1 (see FIG. 1) can display three different images and videos according to a viewing angle. Embodiments are not limited thereto. As an example, at least two or all of the pixel groups PXG1, PXG2, and PXG3 can display the same image and video.

When the display apparatus 1 (see FIG. 1) is used for a vehicle, a screen displayed to the driver DRIVER sitting on the driver's seat and a screen displayed to the passenger CO-DRIVER sitting on the front passenger's seat and the passenger PASSENGER sitting on the rear seat can be distinctly controlled separately, and different screens can be displayed to the driver DRIVER and the passengers CO-DRIVER and PASSENGER.

For example, the first pixel group PXG1 can display an image, a screen, etc. to the driver DRIVER, the second pixel group PXG2 can display an image, a screen, etc. to the passenger PASSENGER sitting on the rear seat, and the third pixel group PXG3 can display an image, a screen, etc. to the passenger CO_DRIVER sitting on the front passenger's seat.

However, the embodiments of the present disclosure are not limited thereto, and one of the pixel groups PXG1, PXG2, and PXG3 can provide a screen displayed to all of the driver DRIVER and the passengers CO-DRIVER and PASSENGER.

For example, the second pixel group PXG2 can provide a separate image and video to only the passenger PASSENGER sitting on the rear seat or provide the same image and video to both the driver DRIVER and the passengers CO-DRIVER and PASSENGER.

A light-shielding member BW (BW1, BW2, or BW3) can be disposed on each pixel group PXG1, PXG2, or PXG3. For example, a first light-shielding member BW1 can be disposed on the pixels PX of the first pixel group PXG1, a second light-shielding member BW2 can be arranged on the pixels PX of the second pixel group PXG2, and a third light-shielding member BW3 can be disposed on the pixels PX of the third pixel group PXG3. Embodiments are not limited thereto. As an example, the microlens ML may not be disposed on at least one of the pixels PX, without being limited thereto. As an example, the microlens ML may not be disposed on at least one of the pixel groups PXG1, PXG2, and PXG3, without being limited thereto. As an example, the light-shielding member BW may not be disposed on at least one of the pixels PX. As an example, the light-shielding member BW may not be disposed on at least one of the pixel groups PXG1, PXG2, and PXG3, without being limited thereto.

The embodiments of the present disclosure are not limited thereto, but the light-shielding member BW can be disposed in the display area DA and may not be disposed in the non-display area NDA.

The light-shielding member BW can absorb and shield light. The light-shielding member BW can be formed of a material capable of absorbing and shielding light. The light-shielding member BW can be formed of at least one selected from poly-acryl (PA), poly-imide (PI), etc., but is not limited thereto.

The light-shielding member BW can be formed in a black-based color, but is not limited thereto. In this case, the light-shielding member BW can be formed of a black pigment and/or dye, but is not limited thereto.

Each light-shielding member BW1, BW2, or BW3 can be disposed at a different location in each pixel group PXG1, PXG2, or PXG3.

For example, the first light-shielding member BW1 can be disposed at one side of the first microlens ML1 in the first direction DR1. The second light-shielding member BW2 can be disposed at one side and the other side of the second microlens ML2 in the first direction DR1. The third light-shielding member BW3 can be disposed at the other side of the third microlens ML3 in the first direction DR1.

A length of each light-shielding member BW1, BW2, or BW3 can be equal to or greater than or smaller than a diameter of the microlens ML1, ML2, or ML3, but is not limited thereto. Here, the length of each light-shielding member BW1, BW2, or BW3 can refer to a length extending in the second direction DR2.

Each light-shielding member BW1, BW2, or BW3 can shield a part of the path of the light emitted from the pixels PX of each pixel group PXG1, PXG2, or PXG3. Each light-shielding member BW1, BW2, or BW3 can shield a different path of the light emitted from the pixels PX of each pixel group PXG1, PXG2, or PXG3.

For example, the first light-shielding member BW1 can shield a part of the light emitted from the pixels PX of the first pixel group PXG1, which travels toward one side in the first direction DR1, the second light-shielding member BW2 can shield a part of the light emitted from the pixels PX of the second pixel group PXG2, which travels toward one side and the other side in the first direction DR1, and the third light-shielding member BW3 can shield a part of the light emitted from the pixels PX of the third pixel group PXG3, which travels toward the other side in the first direction DR1.

The first light-shielding member can shield some of the light emitted from the pixels PX, which travel toward the passengers CO-DRIVER and PASSENGER.

The second light-shielding member BW2 can shield some of the light emitted from the pixels PX of the second pixel group PXG2, which travel toward the driver DRIVER and the passenger CO-DRIVER sitting on the front passenger's seat.

The third light-shielding member BW3 can shield some of the light emitted from the pixels PX of the third pixel group PXG3, which travel toward the driver DRIVER and the passenger PASSENGER sitting on the rear seat.

Since the light-shielding member BW is disposed, it is possible to smoothly shield and control some of the light emitted from the pixels PX of each pixel group PXG1, PXG2, or PXG3, which travels along an undesired path. Accordingly, even when the first pixel group PXG1, the second pixel group PXG2, and the third pixel group PXG3 display different screens, it is possible to reduce, suppress or prevent crosstalk between the different screens displayed to users, thereby suppressing or preventing distortion of the displayed screen and improving the quality of the displayed image and video.

Furthermore, it is possible to reduce, suppress or prevent degradation of luminance of the display apparatus, thereby suppressing or preventing a reduction in luminance efficiency and reducing power consumption.

In addition, since the light-shielding member BW is disposed at an outer side of the microlens ML, the light-shielding member BW can more easily shield or control the path of light emitted from the pixel PX. For example, since the light-shielding member BW is disposed at the outer side of the microlens ML, the light-shielding member BW can be disposed at an end of the path along which the light emitted from the pixels PX travels, thereby lastly shielding and controlling the path of the light emitted from the pixel PX to facilitate the shielding and control of light.

Each microlens ML (ML1, ML2, or ML3) can include a division line DV (DV1, DV2, or DV3). The division line DV can include a first division line DV1, a second division line DV2, and a third division line DV3.

The division line DV can refer to a virtual line that bisects the microlens ML. The microlens ML can be divided into two substantially equal parts through the division line DV, but is not limited thereto. The two parts of the microlens ML divided by the division line DV can include a symmetrical shape, but is not limited thereto, and the two parts of the microlens ML divided by the division line DV can have different shapes and sizes.

The first microlens ML1 can include the first division line DV1, the second microlens ML2 can include the second division line DV2, and the third microlens ML3 can include the third division line DV3.

Each division line DV1, DV2, or DV3 can extend in the second direction DR2 in a plan view as in FIG. 4 and have a thickness in a thickness direction (a third direction DR3). Each division line DV1, DV2, or DV3 can be substantially the same, but is not limited thereto, and the flat surface shape of each division line DV1, DV2, or DV3 can vary according to the shape of each microlens ML1, ML2, or ML3.

Each microlens ML1, ML2, or ML3 can be divided into two parts (a first part and a second part) according to each division line DV1, DV2, or DV3. The first part and the second part of each microlens ML1, ML2, or ML3 can be disposed at one side and the other side of each division line DV1, DV2, or DV3 in the first direction DR1, respectively.

The pixel PX of each pixel group PXG can include a center EC (EC1, EC2, and EC3) of the light-emitting area EA.

A first center EC1 can refer to the center of each light-emitting area EA of the pixel PX of the first pixel group PXG1. A second center EC2 can refer to the center of each light-emitting area EA of the pixel PX of the second pixel group PXG2. A third center EC3 can refer to the center of each light-emitting area EA of the pixel PX of the third pixel group PXG3.

For example, each light-emitting area EA (EA1_1, EA1_2, or EA1_3) of the pixel PX of the first pixel group PXG1 can include the first center EC1. Each light-emitting area EA (EA2_1, EA2_2, or EA2_3) of the pixel PX of the second pixel group PXG2 can include the second center EC2. Each light-emitting area EA (EA3_1, EA3_2, or EA3_3) of the pixel PX of the third pixel group PXG3 can include the third center EC3.

The first center EC1 and the first division line DV1 can be misaligned, the second center EC2 and the second division line DV2 can be misaligned or aligned, and the third center EC3 and the third division line DV3 can be misaligned.

The first center EC1 can be misaligned from the first division line DV1 to one side in the first direction DR1, and the third center EC3 can be misaligned from the third division line DV3 to the other side in the first direction DR1.

A cross-sectional structure of the pixel PX of each pixel group PXG will be described with reference to FIGS. 5 to 7.

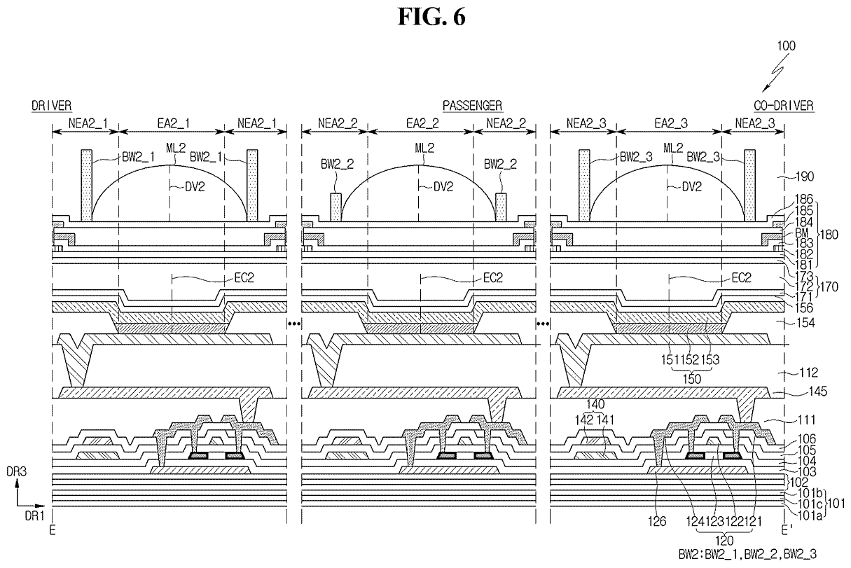

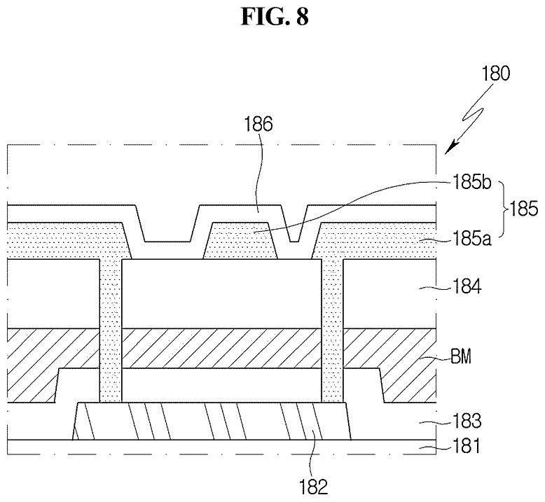

FIG. 5 is a cross-sectional view along line D-D′ in FIG. 4. FIG. 6 is a cross-sectional view along line E-E′ in FIG. 4. FIG. 7 is a cross-sectional view along line F-F′ in FIG. 4. FIG. 8 is a cross-sectional view of a touch part of FIG. 5 taken at a different angle.

A cross-sectional structure of the display area DA will be described with reference to FIGS. 4 to 8.

First, a cross-sectional structure of the first pixel group PXG1 will be described with reference to FIGS. 4, 5, and 8. The description of a configuration of the pixel PX of the first pixel group PXG1 can be applied to the second pixel group PXG2 and the third pixel group PXG3 in the same manner.

The display panel 100 can include a substrate 101, a thin film transistor 120, a storage electrode 140, an light-emitting part 150, an encapsulation part 170, and a touch part 180 in the display area DA. However, the embodiments of the present disclosure are not limited thereto. As an example, at least one of the above-mentioned components can be omitted, or one or more additional components can be further included.

The substrate 101 can provide a space in which various components can be disposed thereon. The substrate 101 can correspond to the flat surface shape of the display panel 100 of FIG. 1. For example, the substrate 101 can include the notch NCP. The substrate 101 can include the display area DA and the non-display area NDA of the display panel 100 in substantially the same manner.

The substrate 101 can include one or more plastic materials, but is not limited thereto, and can include a glass material, or any other insulating materials.

The substrate 101 can be a multilayered substrate including a plurality of substrates of a first substrate 101a, a second substrate 101b, and a third substrate 103c each including a plastic material, such as polyimide, but the embodiments of the present disclosure are not limited thereto. For example, the substrate 101 can be a single substrate formed of a single layer.

The substrate 101 can include a rigid substrate. However, the embodiments of the present disclosure are not limited thereto, and the substrate 101 can include a flexible substrate.

The buffer layer 102 can be disposed on the substrate 101. The buffer layer 102 can reduce, minimize or delay the diffusion of moisture or oxygen penetrating the substrate 101. The buffer layer 102 can be formed by alternately stacking silicon nitride (SiNₓ) and silicon oxide (SiOₓ) at least once, but the embodiments of the present disclosure are not limited thereto.

The disclosure describes that the buffer layer 102 is formed as multiple layers formed of three layers, but the number of layers forming the buffer layer 102 is not limited thereto, and the buffer layer 102 can be formed as a single layer.

A light-shielding layer 126 can be disposed on the buffer layer 102. The light-shielding layer 126 can prevent light from being transmitted to a semiconductor layer 123 of the thin film transistor 120. For example, the semiconductor layer 123 can be disposed to overlap the light-shielding layer 126. The light-shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto. As an example, the light-shielding layer 126 can be omitted depending on the design.

A first insulating layer 103 can be disposed on the light-shielding layer 126. The first insulating layer 103 can prevent a short circuit between a component of the thin film transistor 120 and the light-shielding layer 126. The first insulating layer 103 can be formed of the same material as the buffer layer 102, but the embodiments of the present disclosure are not limited thereto. For example, the first insulating layer 103 can be formed of an inorganic material, such as silicon nitride (SiNₓ) or silicon oxide (SiOₓ), but the embodiments of the present disclosure are not limited thereto.

The thin film transistor 120 can be disposed on the first insulating layer 103. The thin film transistor 120 can include a source electrode 121, a gate electrode 122, a semiconductor layer 123, and a drain electrode 124.

The semiconductor layer 123 can be disposed on the first insulating layer 103. The semiconductor layer 123 can include a metal oxide semiconductor, such as indium-gallium-zinc oxide (IGZO), a silicon-based semiconductor material, such as amorphous silicon or polycrystalline silicon, a compound semiconductor, and an organic semiconductor, but the embodiments of the present disclosure are not limited thereto. The semiconductor layer 123 can include a source area, a drain area, and a channel area between the source area and the drain area.

Since the polycrystalline semiconductor layer has higher mobility than the amorphous semiconductor layer and the oxide semiconductor layer, power consumption can be less, and reliability can be excellent. Accordingly, a driving transistor can be formed of a polycrystalline semiconductor layer, but the embodiments of the present disclosure are not limited thereto.

A second insulating layer 104 can be disposed on the semiconductor layer 123. The second insulating layer 104 can be formed of the same material as the first insulating layer 103, but the embodiments of the present disclosure are not limited thereto. The second insulating layer 104 can prevent a short circuit between the semiconductor layer 123 and another component of the thin film transistor 120.

The gate electrode 122 can be disposed on the second insulating layer 104. The gate electrode 122 can be disposed on the second insulating layer 104 to overlap the channel area of the semiconductor layer 123. The gate electrode 122 can be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The gate electrode 122 can be disposed along with the gate line, but the embodiments of the present disclosure are not limited thereto.

A third insulating layer 105 can be disposed on the gate electrode 122. The third insulating layer 105 can be formed of the same material as the first insulating layer 103 or the second insulating layer 104, but the embodiments of the present disclosure are not limited thereto.

The storage electrode 140 can be disposed to be spaced apart from the thin film transistor 120. The storage electrode 140 can include a first storage electrode 141 and a second storage electrode 142.

The first storage electrode 141 can be formed of the same material as the gate electrode 122 and formed on the same layer, but the embodiments of the present disclosure are not limited thereto.

The second storage electrode 142 can be disposed on the first storage electrode 141. The second storage electrode 142 can be disposed on the third insulating layer 105, and the third insulating layer 105 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

A fourth insulating layer 106 can be disposed on the second storage electrode 142. The fourth insulating layer 106 can be formed of the same material as the first insulating layer 103, the second insulating layer 104, or the third insulating layer 105, but the embodiments of the present disclosure are not limited thereto.

The source electrode 121 and the drain electrode 124 can be disposed on the fourth insulating layer 106.

The source electrode 121 and the drain electrode 124 can be electrically connected to the semiconductor layer 123 through contact holes. The source electrode 121 and the drain electrode 124 can be formed of a metallic material. For example, the source electrode 121 and the drain electrode 124 can be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The source electrode 121 and the drain electrode 124 can be disposed along with the data line. For example, the data line can be formed of the same material as the source electrode 121 and the drain electrode 124 and formed on the same layer, but the embodiments of the present disclosure are not limited thereto.

The thin film transistor 120 can be a driving transistor, and although not illustrated, the display panel 100 can further include a switching transistor, a sensing transistor etc., but the embodiments of the present disclosure are not limited thereto.

A first protective layer 111 can be disposed on the source electrode 121 and the drain electrode 124.

The first protective layer 111 can planarize an upper portion of the thin film transistor 120 and protect the thin film transistor 120. The first protective layer 111 can be formed of an organic material. For example, the first protective layer 111 can be formed of an organic material including an acrylic resin, an epoxy resin, a phenolic resin, a polyamide resin, or a polyimide resin, but the embodiments of the present disclosure are not limited thereto. As an example, the first protective layer 111 can be formed of an inorganic material, or can be formed of both of the organic material and the inorganic material, without being limited thereto.

The second protective layer 112 can be disposed on the first protective layer 111. The second protective layer 112 can be formed of the same material as or a different material from the first protective layer 111, but the embodiments of the present disclosure are not limited thereto.

As an example, a connection electrode 145 can be disposed between the first protective layer 111 and the second protective layer 112, without being limited thereto. As an example, the connection electrode 145 can be omitted depending on the design.

The connection electrode 145 can electrically connect the thin film transistor 120 to the light-emitting part 150. The connection electrode 145 can be formed of the same material as the source electrode 121 and the drain electrode 124, but the embodiments of the present disclosure are not limited thereto.

The connection electrode 145 can come into contact with the drain electrode 124 through the contact hole formed in the first protective layer 111 and can be electrically connected to the drain electrode 124.

The connection electrode 145 can be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include an anode electrode 151, an organic layer 152, and a cathode electrode 153.

The anode electrode 151 can be disposed on the second protective layer 112. The anode electrode 151 can be electrically connected to the thin film transistor 120 through a contact hole formed in the second protective layer 112.

As an example, the anode electrode 151 can be a reflective electrode that reflects light, but the embodiments of the present disclosure are not limited thereto. The anode electrode 151 can include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

For example, the cathode electrode 153 can include a material, such as indium tin oxide (ITO) or indium zinc oxide (IZO), but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto. As an example, at least one of the hole transporting layer, the hole injecting layer, the electron blocking layer, the p-type charge generation layer, the electron transporting layer, the electron injecting layer, the hole blocking layer, the n-type charge generation layer can be omitted, depending on the design.

The organic layer 152 can be an organic light-emitting layer, an inorganic light-emitting layer, a quantum dot light-emitting layer, a micro light-emitting diode, a mini light-emitting diode, etc., but the embodiments of the present disclosure area are not limited thereto. For example, the organic layer 152 of the display panel 100 according to one example embodiment of the present disclosure can include an organic light-emitting layer. The organic layer 152 can be a white light-emitting layer, but the embodiments of the present disclosure are not limited thereto.

The cathode electrode 153 can be disposed on the organic layer 152. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

The capping layer 156 can be further disposed on the cathode electrode 153. The capping layer 156 can minimize damage to the cathode electrode 153 of the light-emitting element EL and the organic layers 152 located below the cathode electrode 153 from an external light source. The capping layer 156 can be formed of an organic or inorganic film. As an example, the capping layer 156 can be omitted depending on the design.

The capping layer 156 can be disposed using a material, such as LiF or the like, as an inorganic film and can further include an organic film, but the embodiments of the present disclosure are not limited thereto. For example, the capping layer 156 can be formed of the stacking structure of an organic film and an inorganic film, and a thickness of the organic film can differ from a thickness of the inorganic film. In this case, as an example, the thickness of the organic film can be greater than the thickness of the inorganic film. As another example, the capping layer 156 can be formed of two or more layers by stacking materials having different refractive indexes, without being limited thereto. Accordingly, it is possible to increase the light efficiency of the display panel 100.

A bank 154 can be disposed to expose the anode electrode 151. The bank 154 can define an opening (or an light-emitting area EA of the pixel PX) and can be disposed to cover an edge of the anode electrode 151. The organic layer 152 can be disposed in the opening of the pixel PX. For example, the organic layer 152 can be disposed on the anode electrode 151 exposed by the bank 154.

However, the embodiments of the present disclosure are not limited thereto, and the organic layer 152 can be disposed both in the opening (the light-emitting area EA of the pixel PX) and on the bank 154. For example, the organic layer 152 can be disposed in the entirety of the display area DA of the display panel 100.

The bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be an opaque bank. When the bank 154 is formed of a material containing black pigment or black dye, it is possible to shield external light or light reflected from the outside, thereby further increasing the luminance of the display apparatus.

A spacer can be further disposed on the bank 154. The spacer can be formed of the same material as the bank 154, but the embodiments of the present disclosure are not limited thereto. The spacer can reduce or prevent sagging of a mask during a mask process, thereby suppressing or preventing defects, such as imprinting, scratching, or the like, on the display panel 100.

The encapsulation part 170 can be disposed on the bank 154 or the light-emitting part 150. The encapsulation part 170 can include one or more insulating layers. For example, the encapsulation part 170 can include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 can include one or more inorganic layers and one or more organic layers. For example, the first inorganic encapsulation layer 171 and the second inorganic encapsulation layer 173 can include an inorganic material, and the organic encapsulation layer 172 can include an organic material, but the embodiments of the present disclosure are not limited thereto.

The first inorganic encapsulation layer 171 and the second inorganic encapsulation layer 173 can be disposed to extend around the dam part DMP, and the organic encapsulation layer 172 can be ended inside the dam part DMP. For example, the organic encapsulation layer 172 can be disposed inside an area surrounded by the dam part DMP without extending beyond the dam part DMP.

The touch part 180 can be disposed on the encapsulation part 170. The touch part 180 can include a touch buffer layer 181, a first touch electrode 182, a first touch insulating layer 183, a black matrix BM, a second touch insulating layer 184, a second touch electrode 185, and a third touch insulating layer 186. As an example, at least one of these components or the entire touch part 180 can be omitted depending on the design.

The touch buffer layer 181 can be disposed on the encapsulation part 170. For example, the touch buffer layer 181 can be disposed on the second inorganic encapsulation layer 173. The touch buffer layer 181 can be formed of the same material as the buffer layer 102, but the embodiments of the present disclosure are not limited thereto.

The first touch electrode 182 can be disposed on the touch buffer layer 181.

The first touch insulating layer 183 can be disposed on the first touch electrode 182. The first touch insulating layer 183 can be formed of silicon oxide (SiOₓ), silicon nitride (SiNₓ), or multiple layers thereof, but the embodiments of the present disclosure are not limited thereto.

The black matrix BM can be disposed on the first touch insulating layer 183. The black matrix BM can include materials capable of absorbing light. The black matrix BM can include a black pigment or dye, but is not limited thereto. The black matrix BM can prevent a defect, such as light leakage that can occur between the pixels PX.

The second touch insulating layer 184 can be disposed on the black matrix BM. The second touch insulating layer 184 can include an organic insulation material. For example, the second touch insulating layer 184 can be formed of photo acryl, benzocyclobutene (BCB), polyimide (PI), or polyamide (PA), but is not limited thereto.

The second touch electrode 185 can be disposed on the second touch insulation layer 184. The second touch electrode 185 can include a 1a touch electrode 185a extending in the first direction DR1 and a 1b touch electrode 185b extending in the second direction DR2 different from the first direction, without being limited thereto.

The first touch electrode 182 can be electrically connected to a 1a touch electrode 185a through a contact hole formed in the second touch insulating layer 184. For example, the 1a touch electrode 185a and the first touch electrode 182 can extend in the first direction DR1.

The first touch electrode 182 and the second touch electrode 185 can include a metallic material. For example, the sensor electrode 185 and the bridge electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

One of the first touch electrode 182 and the second touch electrode 185 can include a function of detecting touch, and the other can include a function of driving touch, but the embodiments of the present disclosure are not limited thereto.

The third touch insulating layer 186 can be disposed on the second touch electrode 185. The third touch insulating layer 186 can be formed of the same material as the first touch insulating layer 183, but is not limited thereto.

The microlens ML (ML1, ML2, and ML3) can be disposed on the third touch insulating layer 186. The microlens ML can include a hemispherical or semi-cylindrical shape, but is not limited thereto. The shape of the microlens ML can vary according to the size, shape, etc. of the light-emitting area EA.

Each microlens ML1, ML2, or ML3 can control a path of light emitted from each pixel group PXG1, PXG2, or PXG3. Each microlens ML1, ML2, or ML3 can adjust the path of the light emitted from each pixel group PXG1, PXG2, or PXG3 in a different direction.

Accordingly, each pixel group PXG1, PXG2, or PXG3 can display a different image and video, and the display apparatus 1 (see FIG. 1) can display three different images and videos according to a viewing angle.

In addition, by arranging the microlens ML (ML1, ML2, and ML3), it is possible to secure a wide viewing angle characteristic, increase luminance, and block leaked light, reflected light, etc., thereby preventing light leakage.

In the first pixel group PXG1, the first microlens ML1 can be disposed on the third touch insulating layer 186.

The light-shielding member BW (BW1, BW2, and BW3) can be disposed on the same layer as the microlens ML. For example, the light-shielding member BW (BW1, BW2, and BW3) can be disposed on the third touch insulating layer 186, but is not limited thereto. The light-shielding member BW (BW1, BW2, and BW3) can be disposed on a different layer from the microlens ML.

In the first pixel group PXG1, the first light-shielding member BW1 can be disposed on the third touch insulating layer 186.

The first light-shielding member BW1 can be disposed at one side of the first microlens ML1 in the first direction DR1. Accordingly, the first light-shielding member BW1 can shield some of the light emitted from the pixels PX of the first pixel group PXG1, which travel toward one side in the first direction DR1. For example, it is possible to shield some of the light emitted from the pixels PX of the first pixel group PXG that display the screen to the driver DRIVER, which travel toward the passengers CO-DRIVER and PASSENGER.

The first light-shielding member BW1 can come into direct contact with the first microlens ML1, but is not limited thereto, and the first light-shielding member BW1 can be disposed to be spaced apart from the first microlens ML1.

As an example, the first light-shielding member BW1 can have a different height according to the location of the pixel PX, or can have the same height regardless of the location of the pixel PX. Here, the height of the first light-shielding member BW1 can refer to a height (a length) in the thickness direction (the third direction DR3). Accordingly, it is possible to shield light traveling along an undesired path and minimize the reduction in luminance.

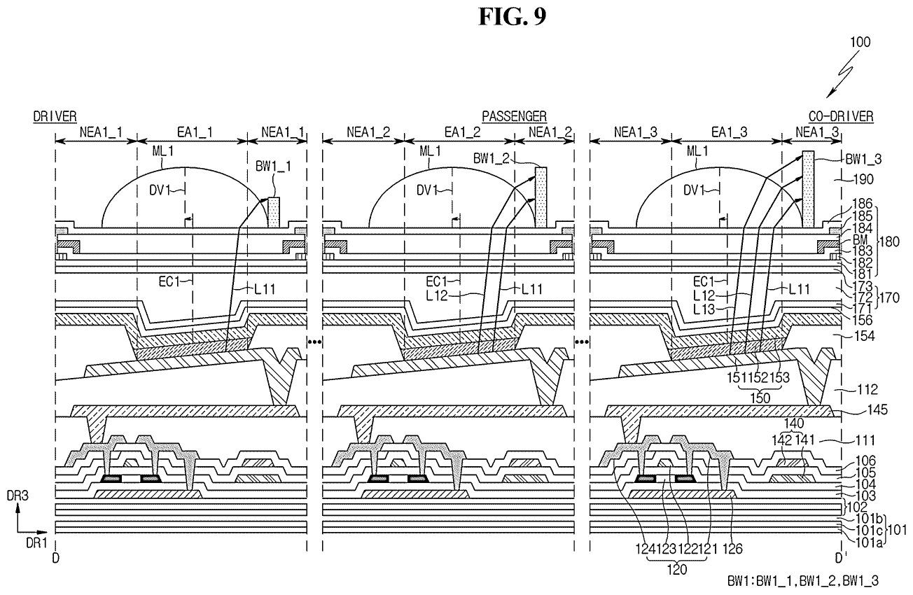

FIG. 9 is a schematic view illustrating a path of light in FIG. 5.

Referring further to FIG. 9, the height of the first light-shielding member BW1 can vary according to the location of the pixel PX. Here, the height of the first light-shielding member BW1 can refer to a height (a length) in the thickness direction (the third direction DR3).

The height of the first light-shielding member BW1 can increase toward one side in the first direction DR1. Specifically, the first light-shielding member BW1 can be disposed in each of the plurality of pixels PX disposed in the first pixel group PXG1, and the plurality of pixels PX can be arranged in the first direction DR1. In this case, among the pixels PX of the first pixel group PXG1 arranged in the first direction DR1, the height of the first light-shielding member BW1 of the pixel PX disposed at one side in the first direction DR1 can increase.

For example, the first light-shielding member BW1 can include a 1_1 light-shielding member BW1_1 disposed in the 1_1 pixel PX1_1, a 1_2 light-shielding member BW1_2 disposed in the 1_2 pixel PX1_2, and a 1_3 light-shielding member BW1_3 disposed in the 1_3 pixel PX1_3. The 1_3 pixel PX1_3 can be disposed at one side of the 1_2 pixel PX1_2 in the first direction DR1, and the 1_2 pixel PX1_2 can be disposed at one side of the 1_1 pixel PX1_1 in the first direction DR1. In this case, a height of the 1_3 light-shielding member BW1_3 can be higher than a height of the 1_2 light-shielding member BW1_2, and the height of the 1_2 light-shielding member BW1_2 can be higher than a height of the 1_1 light-shielding member BW1_1.

Among the pixels PX of the first pixel group PXG1, a pixel PX close to the driver DRIVER does not have a large range of angles of light traveling toward the passengers CO-DRIVER and PASSENGER due to its location, but the range of angles of the light traveling toward the passenger CO-DRIVER and PASSENGER can increase toward the passengers CO-DRIVER and PASSENGER.

For example, the pixel PX disposed closer to one side in the first direction DR1 among the pixels PX of the first pixel group PXL1 can have a larger range of the angles of the light traveling toward the passengers CO-DRIVER and PASSENGER.

For example, the 1_1 light-shielding member BW1_1 can shield 11^{th} light L11 among the light traveling toward the passengers CO-DRIVER and PASSENGER, the 1_2 light-shielding member BW1_2 can shield the 11^{th} light L11 and 12^{th} light L12 among the light traveling toward the passengers CO-DRIVER and PASSENGER, and the 1_3 light-shielding member BW1_3 can shield the 11^{th} light L11, the 12^{th} light L12, and 13^{th} light L13 among the light traveling toward the passengers CO-DRIVER and PASSENGER.

By arranging the first light-shielding members BW1 so that at least some thereof have different heights, it is possible to reduce or minimize light shielding, thereby suppressing or preventing the reduction in luminance and smoothly shielding the light traveling in the undesired direction (toward the passengers CO-DRIVER and PASSENGER).

A lens protective layer 190 can be disposed on the microlens ML (ML1, ML2, and ML3 and the light-shielding member BW. The lens protective layer 190 can include an organic insulation material, but is not limited thereto. The lens protective layer 190 can protect the microlens ML by covering the microlens ML.

The lens protective layer 190 can cover both the microlens ML and the light-shielding member BW. The lens protective layer 190 can come into direct contact with the light-shielding member BW.

A refractive index of the lens protective layer 190 can be smaller than a refractive index of the microlens ML. Accordingly, due to a difference in refractive index between the microlens ML and the lens protective layer 190, light that has passed through the microlens ML can be prevented from being reflected toward the substrate 101.

Subsequently, a cross-sectional structure of the second pixel group PXG2 will be described with reference to FIGS. 4 and 6. The overlapping contents of those described in the first pixel group PXG1 will be omitted or briefly described.

Even in the second pixel group PXG2, the substrate 101, the thin film transistor 120, the storage electrode 140, the light-emitting part 150, the encapsulation part 170, the touch part 180, the lens protective layer 190, etc. can be disposed. The overlapping descriptions thereof will be omitted.

In the second pixel group PXG2, the second microlens ML2 can be disposed on the third touch insulating layer 186.

In the second pixel group PXG2, the second light-shielding member BW2 can be disposed on the third touch insulating layer 186.

The second light-shielding member BW2 can be disposed at one side and the other side of the second microlens ML2 in the first direction DR1. Accordingly, the second light-shielding member BW2 can shield some of the light emitted from the pixels PX of the second pixel group PXG2, which travel toward one side and the other side in the first direction DR1. For example, it is possible to shield some of the light emitted from the pixels PX of the second pixel group PXG that display the screen to the passenger PASSENGER sitting on the rear seat, which travel toward the driver DRIVER and the passenger CO-DRIVER.

The second light-shielding member BW2 can come into direct contact with the second microlens ML2, but is not limited thereto, and the second light-shielding member BW2 can be disposed to be spaced apart from the second microlens ML2.

Each of the second light-shielding members BW2 disposed at the one side and the other side of the second microlens ML2 in the first direction DR1 can be formed in the form of an island, but is not limited thereto.

The second light-shielding member BW2 can have a different height according to the location of the pixel PX. Here, the height of the second light-shielding member BW2 can refer to a height (a length) in the thickness direction (the third direction DR3). Accordingly, it is possible to shield light traveling along an undesired path and reduce or minimize the reduction in luminance.

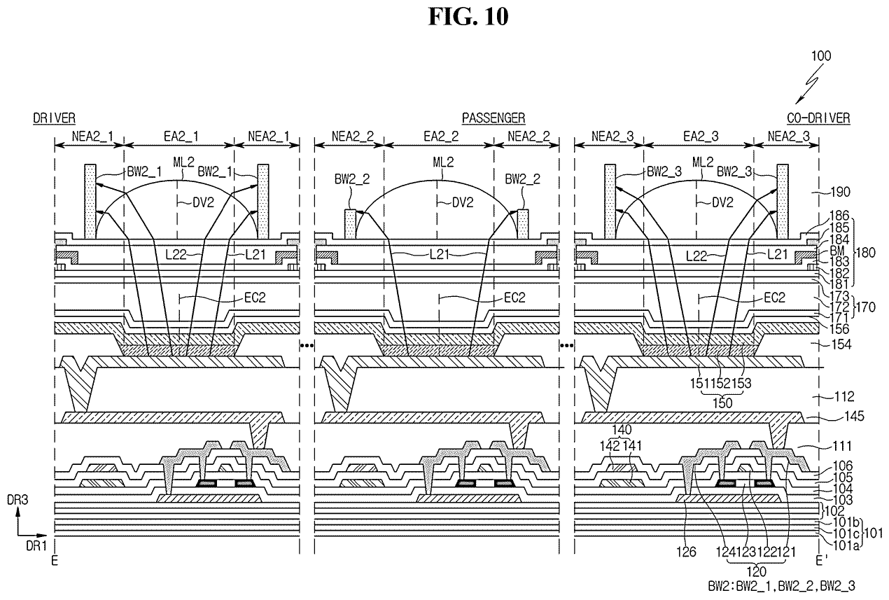

FIG. 10 is a schematic view illustrating a path of light in FIG. 6.

Referring further to FIG. 10, the second light-shielding member BW2 can have a height that increases from a middle area of the display area DA toward one side and the other side in the first direction DR1. Specifically, the second light-shielding member BW2 can be disposed in each of the plurality of pixels PX disposed in the second pixel group PXG2, and the plurality of pixels PX can be arranged in the first direction DR1. In this case, among the pixels PX of the second pixel group PXG2 arranged in the first direction DR1, the height of the second light-shielding member BW2 of the pixel PX disposed at one side in the first direction DR1 can increase.

For example, the second light-shielding member BW2 can include a 2_1 light-shielding member BW2_1 disposed in the 2_1 pixel PX2_1, a 2_2 light-shielding member BW2_2 disposed in the 2_2 pixel PX2_2, and a 2_3 light-shielding member BW2_3 disposed in the 2_3 pixel PX2_3. The 2_3 pixel PX2_3 can be disposed at one side of the 2_2 pixel PX2_2 in the first direction DR1, and the 2_1 pixel PX2_1 can be disposed at the other side of the 2_2 pixel PX2_2 in the first direction DR1. In this case, a height of the 2_3 light-shielding member BW2_3 and a height of the 2_1 light-shielding member BW2_1 can be higher than a height of the 2_2 light-shielding member BW2_2.

Among the pixels PX of the second pixel group PXG2, a pixel PX close to the passenger PASSENGER sitting on the rear seat can be disposed near the center of the display area DA, and due to its location, the range of angles of light traveling toward the driver DRIVER and the passenger CO-DRIVER is not large, but a pixel PX closer to the driver DRIVER and the passenger CO-DRIVER can have a larger range of the angles of the light traveling toward the driver DRIVER and the passenger CO-DRIVER.

For example, the 2_2 light-shielding member BW2_2 can shield 21^{st} light L21 among the light traveling toward the driver DRIVER and the passenger CO-DRIVER, and the 2_1 light-shielding member BW2_1 and the 2_3 light-shielding member BW2_3 can shield the 21^{st} light L21 and 22^{nd} light L22 among the light traveling toward the driver DRIVER and the passenger CO-DRIVER.

By arranging the second light-shielding members BW2 so that at least some thereof have different heights, it is possible to reduce or minimize light shielding, thereby suppressing or preventing the reduction in luminance and smoothly shielding the light traveling in the undesired direction (toward the driver DRIVER and the passenger CO-DRIVER).

Subsequently, a cross-sectional structure of the third pixel group PXG3 will be described with reference to FIGS. 4 and 7. The overlapping contents of those described in the first pixel group PXG1 will be omitted or briefly described.

Even in the third pixel group PXG3, the substrate 101, the thin film transistor 120, the storage electrode 140, the light-emitting part 150, the encapsulation part 170, the touch part 180, the lens protective layer 190, etc. can be disposed. The overlapping descriptions thereof will be omitted.

In the third pixel group PXG3, the third microlens ML3 can be disposed on the third touch insulating layer 186.

In the third pixel group PXG3, the third light-shielding member BW3 can be disposed on the third touch insulating layer 186.

The third light-shielding member BW3 can be disposed at the other side of the third microlens ML3 in the first direction DR1. Accordingly, the third light-shielding member BW3 can shield some of the light emitted from the pixels PX of the third pixel group PXG3, which travel toward the other side in the first direction DR1. For example, it is possible to shield some of the light emitted from the pixels PX of the third pixel group PXG that display the screen to the passenger CO-DRIVER sitting on the front passenger's seat, which travel toward the passenger PASSENGER sitting on the rear seat.

The third light-shielding member BW3 can come into direct contact with the third microlens ML3, but is not limited thereto, and the third light-shielding member BW3 can be disposed to be spaced apart from the third microlens ML3.

The third light-shielding member BW3 can have a different height according to the location of the pixel PX. Here, the height of the third light-shielding member BW3 can refer to a height (a length) in the thickness direction (the third direction DR3). Accordingly, it is possible to shield light traveling along an undesired path and reduce or minimize the reduction in luminance.

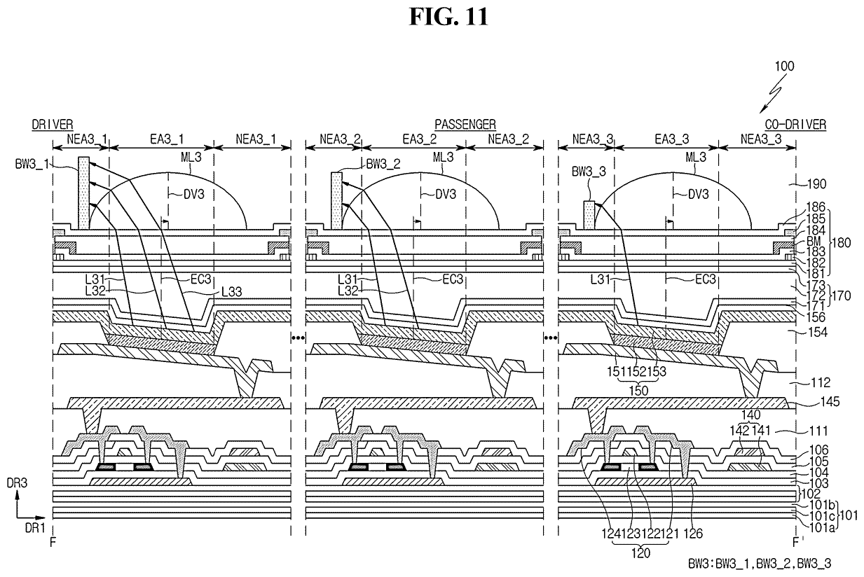

FIG. 11 is a schematic view illustrating a path of light in FIG. 7.

Referring further to FIG. 11, the third light-shielding member BW3 can have a height that increases toward the other side in the first direction DR1. Specifically, the third light-shielding member BW3 can be disposed in each of the plurality of pixels PX disposed in the third pixel group PXG3, and the plurality of pixels PX can be arranged in the first direction DR1. In this case, among the pixels PX of the third pixel group PXG3 arranged in the first direction DR1, the height of the third light-shielding member BW3 of the pixel PX disposed at the other side in the first direction DR1 can increase.

For example, the third light-shielding member BW3 can include a 3_1 light-shielding member BW3_1 disposed in the 3_1 pixel PX3_1, a 3_2 light-shielding member BW3_2 disposed in the 3_2 pixel PX3_2, and a 3_3 light-shielding member BW3_3 disposed in the 3_3 pixel PX3_3. The 3_3 pixel PX3_3 can be disposed at one side of the 3_2 pixel PX3_2 in the first direction DR1, and the 3_2 pixel PX3_2 can be disposed at one side of the 3_1 pixel PX3_1 in the first direction DR1. In this case, a height of the 3_1 light-shielding member BW3_1 can be higher than a height of the 3_2 light-shielding member BW3_2, and the height of the 3_2 light-shielding member BW3_2 can be higher than a height of the 3_3 light-shielding member BW3_3.

Among the pixels PX of the third pixel group PXG3, a pixel PX close to the passenger CO-DRIVER sitting on the front passenger's seat does not have a large range of angles of light traveling toward the driver DRIVER and the passenger PASSENGER sitting on the rear seat, but a pixel PX closer to the driver DRIVER and the passenger PASSENGER sitting on the rear seat can have a larger range of the angles of the light traveling toward the driver DRIVER and the passenger PASSENGER.

For example, the pixel PX disposed closer to the other side in the first direction DR1 among the pixels PX of the third pixel group PXL1 can have a larger range of the angles of the light traveling toward the driver DRIVER and the passenger PASSENGER sitting on the rear seat.

For example, the 3_3 light-shielding member BW3_3 can shield 31^{st} light L31 among the light traveling toward the driver DRIVER and the passenger PASSENGER sitting on the rear seat, the 3_2 light-shielding member BW3_2 can shield the 31^{th} light L31 and 32^{th} light L32 among the light traveling toward the driver DRIVER and the passenger PASSENGER sitting on the rear seat, and the 3_1 light-shielding member BW3_1 can shield the 31^{th} light L31, the 32^{th} light L32, and 33^{th} light L33 among the light traveling toward the driver DRIVER and the passenger PASSENGER sitting on the rear seat.

By arranging the third light-shielding members BW3 so that at least some thereof have different heights, it is possible to reduce or minimize light shielding, thereby suppressing or preventing the reduction in luminance and smoothly shielding the light traveling in the undesired direction (toward the driver DRIVER and the passenger PASSENGER sitting on the rear seat).

As an example, an upper surface of the second protective layer 112 can be disposed to be inclined, for example, with respect to an upper surface of the substrate 101. As an example, the upper surface of the second protective layer 112 can be disposed to be inclined toward different directions in the first pixel group PXG1, the second pixel group PXG2, and the third pixel group PXG3. As an example, the upper surface of the second protective layer 112 can be disposed to be inclined toward the other side in the first direction DR1 in the first pixel group PXG1. As an example, the upper surface of the second protective layer 112 can be disposed to be inclined toward the one side in the first direction DR1 in the third pixel group PXG3. As an example, the upper surface of the second protective layer 112 can be disposed to be in parallel with the upper surface of the substrate 101 in the second pixel group PXG3. As an example, the light emitting part 150 can be disposed to be inclined correspondingly with the upper surface of the second protective layer 112. As an example, the upper surface of the encapsulation part 170 can be planar. Embodiments are not limited thereto. As an example, the upper surface of the second protective layer 112 can be disposed to be in parallel with the upper surface of the substrate 101 in each of the first pixel group PXG1, the second pixel group PXG2, and the third pixel group PXG3.

Hereinafter, a cross-sectional structure of the non-display area NDA of the display apparatus 1 will be described. The same content as that described in the cross-sectional structure of the display area DA will be briefly described or omitted.

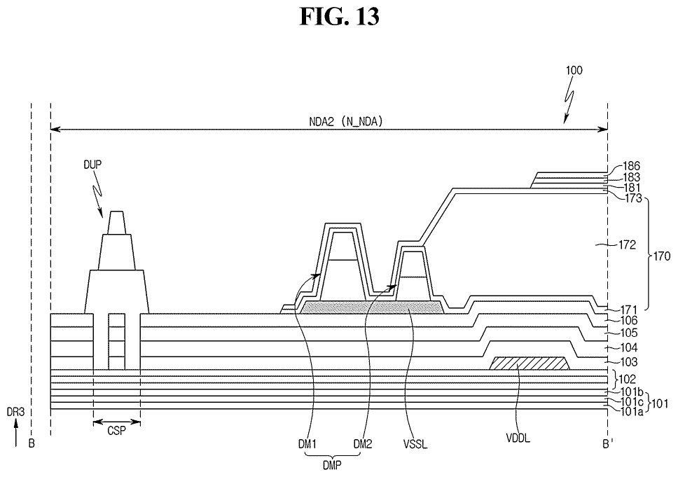

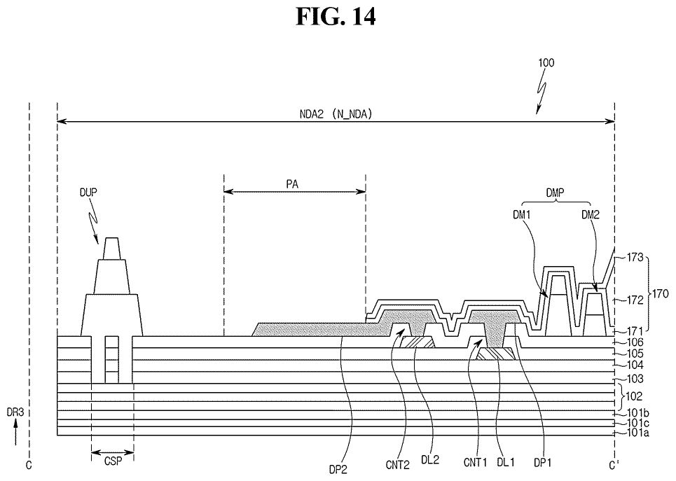

FIG. 12 illustrates a cross-sectional structure of the first non-display area NDA1. FIGS. 13 and 14 illustrate cross-sectional structures of a notch non-display area N_NDA of the second non-display area NDA2. The descriptions of FIGS. 13 and 14 can also be applied to the extension non-display area E_NDA in substantially the same manner.

Subsequently, referring further to FIGS. 1, 3, and 12 to 14, the display panel 100 can further include the gate control transistor G120, the low-potential voltage line VSSL, the dam part DMP, the plurality of pads VSSP, VDDP, and DP disposed in the pad area PA, the data line DL (DL1 and DL2), and a crack prevention pattern CSP, which are disposed in the non-display area NDA.

The gate control transistor G120 can have substantially the same configuration as the thin film transistor 120 of the pixel PX and can be formed along with the thin film transistor 120 of the pixel PX by the same process, but is not limited thereto.

The gate control transistor G120 can include a control source electrode G121, a control gate electrode G122, a control semiconductor layer G123, and a control drain electrode G124.

A light-shielding layer can be further disposed under the gate control transistor G120. One of the control source electrode G121 and the control drain electrode G124 can be electrically connected in contact with the light-shielding layer, but is not limited thereto.

The low-potential voltage line VSSL can be disposed on the fourth insulating layer 106, without being limited thereto. The low-potential voltage line VSSL can be formed of the same metal layer as the source electrode 121 and the drain electrode 124 of the thin film transistor 120, but is not limited thereto.

The display panel 100 can further include a low-potential connection electrode CE. The low-potential connection electrode CE can connect the low-potential voltage line VSSL to the cathode electrode 153.

The low-potential connection electrode CE can be disposed on the second protective layer 112. The bank 154 can be disposed on the low-potential connection electrode CE. The low-potential connection electrode CE can be disposed on the same layer as the anode electrode 151 and can include the same material as the anode electrode 151, and the low-potential connection electrode CE and the anode electrode 151 can be formed together using one mask by the same process, but the embodiments of the present disclosure are not limited thereto.

The display panel 100 can further include an exposed part OP. The exposed part OP can expose at least a part of the low-potential voltage line VSSL by recessing the first protective layer 111 and the second protective layer 112.

The exposed part OP can be defined by the first protective layer 111 and the second protective layer 112. The exposed part OP can be defined by a side surface of the first protective layer 111, a side surface of the second protective layer 112, and a side surface of a second dam DM2.

The low-potential connection electrode CE can be electrically connected in contact with the low-potential voltage line VSSL exposed in the exposed part OP. At least a part of the low-potential connection electrode CE can be disposed on the second protective layer 112 and can extend from the second protective layer 112 toward the low-potential voltage line VSSL.

The low-potential connection electrode CE can be further disposed on the side surface of the first protective layer 111 that defines the exposed part OP and the side surface of the second protective layer 112 and can be further disposed on the fourth insulating layer 106 and the low-potential voltage line VSSL that are exposed by the exposed part OP. Accordingly, the low-potential connection electrode CE can come into contact with the low-potential voltage line VSSL.

The low-potential connection electrode CE can be electrically connected to the cathode electrode 153. The low-potential connection electrode CE and the cathode electrode 153 can be electrically connected in contact with each other through a low-potential contact hole C_CNT in an overlapping area. The low-potential contact hole C_CNT can be defined by passing through the bank 154 in the area in which the low-potential connection electrode CE and the cathode electrode 153 overlap each other and can expose the low-potential connection electrode CE.

The dam part DMP can include a first dam DM1 and a second dam DM2. The first dam DM1 and the second dam DM2 can overlap the low-potential voltage line VSSL. Embodiments are not limited thereto. As an example, the dam part DMP can include one or three or more dams. As an example, at least one or more of the three or more dams can overlap the low-potential voltage line VSSL. As an example, at least one or more of the three or more dams may not overlap the low-potential voltage line VSSL.

In the second non-display area NDA2, the first dam DM1 and the second dam DM2 can overlap the low-potential voltage line VSSL. In the first non-display area NDA1, the first dam DM1 and the second dam DM2 can overlap the low-potential voltage line VSSL.

The first dam DM1 can be disposed outside the second dam DM2, but is not limited thereto.

The first dam DM1 can be formed in a multilayered structure. Each layer of the first dam DM1 can include the same material as the second protective layer 112 and the bank 154, and each layer of the first dam DM1, the second protective layer 112, and the bank 154 can be formed together using one mask by the same process, but the embodiments of the present disclosure are not limited thereto.

The second dam DM2 can be formed in a multilayered structure. Each layer of the second dam DM2 can include the same material as the bank 154 and the spacer, and each layer of the second dam DM2, the bank 154, and the spacer can be formed together using one mask by the same process, but the embodiments of the present disclosure are not limited thereto.

As an example, the crack prevention pattern CSP can be disposed at an outermost edge of the non-display area NDA, without being limited thereto. The crack prevention pattern CSP can be defined by recessing at least one of the inorganic films disposed on the substrate 101. As an example, the crack prevention pattern CSP can be omitted depending on the design.

For example, the crack protection pattern CSP can be defined by recessing the first insulating layer 103, the second insulating layer 104, the third insulating layer 105, and the fourth insulating layer 106, but is not limited thereto.

As an example, a crack dummy pattern DUP can be further disposed on the crack protection pattern CSP, without being limited thereto. The crack dummy pattern DUP can fill the recessed crack protection pattern CSP. The crack dummy pattern DUP can be formed of multiple layers. For example, the crack dummy pattern DUP can be formed of three layers. Layers of the crack dummy pattern DUP can include the same material as the first protective layer 111, the second protective layer 112, and the bank 154.

As an example, the high-potential voltage line VDDL can be disposed on the buffer layer 102 and covered by the first insulating layer 103, without being limited thereto. The high-potential voltage line VDDL can include the same material as the light-shielding layer 126, and the high-potential voltage line VDDL and the light-shielding layer 126 can be formed together using one mask by the same process, but the embodiments of the present disclosure are not limited thereto.

Although not illustrated, the high-potential voltage pad VDDP can be disposed on the same layer as the source electrode 121 and the drain electrode 124, can include the same material as the source electrode 121 and the drain electrode 124, and can be formed together using one mask by the same process as the source electrode 121 and the drain electrode 124, but is not limited thereto.

In this case, the high-potential voltage pad VDDP can be electrically connected in contact with the high-potential voltage line VDDL through the high-potential contact hole S_CNT that exposes the high-potential voltage line VDDL.

However, the embodiments of the present disclosure are not limited thereto, and the high-potential voltage line VDDL can be disposed on the same layer as the source electrode 121 and the drain electrode 124 and can include the same material as the source electrode 121 and the drain electrode 124, and the high-potential voltage line VDDL, the source electrode 121, and the drain electrode 124 can be formed together using one mask by the same process.

As an example, the first data pad DP1 and the second data pad DP2 can be disposed on the fourth insulating layer 106, without being limited thereto. The first data pad DP1 and the second data pad DP2 can be disposed on the same layer as the source electrode 121 and the drain electrode 124, can include the same material as the source electrode 121 and the drain electrode 124, and can be formed together using one mask by the same process as the source electrode 121 and the drain electrode 124, but are not limited thereto.

As an example, the first data line DL1 can be disposed on the second insulating layer 104 and covered by the third insulating layer 105, without being limited thereto. The first data line DL1 can include the same material as the gate electrode 122 and can be formed together using one mask by the same process as the gate electrode 122, but is not limited thereto.

As an example, the second data line DL2 can be disposed on the third insulating layer 105 and covered by the fourth insulating layer 106, without being limited thereto. The second data line DL2 can include the same material as the second storage electrode 142 and can be formed together using one mask by the same process as the second storage electrode 142, but is not limited thereto.

The first data line DL1 can be electrically connected in contact with the first data pad DP1 through the first data contact hole CNT1. The second data line DL2 can be electrically connected in contact with the second data pad DP2 through the second data contact hole CNT2.

The crack prevention pattern CSP can be disposed outside the pad area PA. The crack prevention pattern CSP can be disposed between the ends of the pad area PA and the non-display area NDA2.

However, the plurality of pads VSSP, VDDP, and DP may not be covered by a plurality of inorganic films. The plurality of inorganic films disposed on the fourth insulating layer 106 can expose the plurality of pads VSSP, VDDP, and DP. The plurality of inorganic films disposed on the fourth insulating layer 106 may not be disposed in the pad area PA.

Accordingly, the flexible film COF can be configured so that at least a part thereof is disposed to overlap the pad area PA and attached to the display panel 100, and the flexible film COF can be electrically connected in contact with the plurality of pads VSSP, VDDP, and DP of the pad area PA.

Hereinafter, other embodiments of the present disclosure will be described. For contents substantially the same as those described with reference to FIGS. 1 to 14 among components included in other embodiments, the same reference numerals are given, and the overlapping contents can be omitted or briefly described.

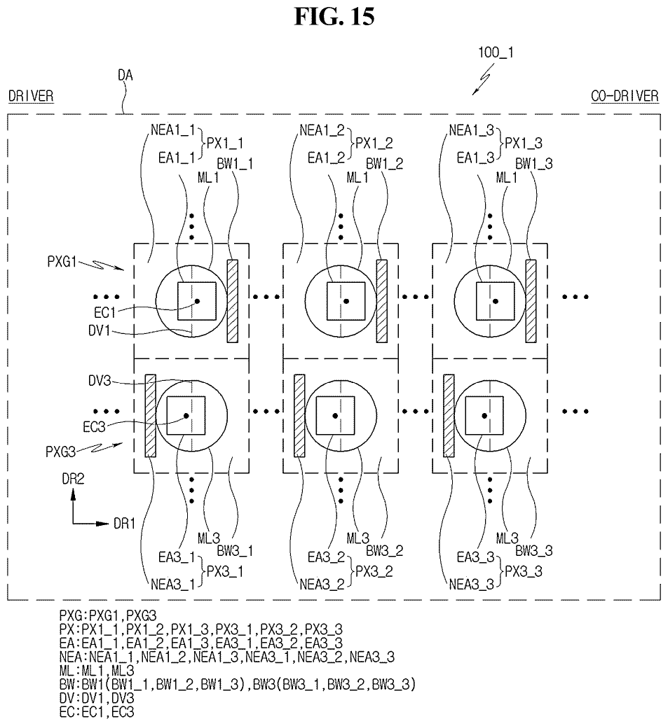

FIG. 15 is a plan view illustrating a pixel arrangement of a display panel according to another example embodiment of the present disclosure.

Referring to FIG. 15, a display panel 100_1 according to the present embodiment can include the first pixel group PXG1 and the third pixel group PXG3 of FIG. 4, but may not include the second pixel group PXG2.

The first pixel group PXG1 and the third pixel group PXG3 can be disposed alternately and repeatedly in the second direction DR2. The first microlens ML1 and the first light-shielding member BW1 can be disposed on the pixels PX included in the first pixel group PXG1. The third microlens ML3 and the third light-shielding member BW3 can be disposed on the pixels PX included in the third pixel group PXG3.

Accordingly, each pixel group PXG1 or PXG3 can display a different image and video, and the display apparatus 1 (see FIG. 1) can display two different images and videos according to a viewing angle.

When the display panel 100_1 is used in a display apparatus for a vehicle, a screen displayed to the driver DRIVER sitting on the driver's seat and a screen displayed to the passenger CO-DRIVER sitting on the front passenger's seat can be distinctly controlled separately, and different screens can be displayed to the driver DRIVER and the passenger CO-DRIVER.

Even in this case, since the light-shielding members BW1 and BW3 are disposed on the pixel PX, it is possible to smoothly shield and control some of the light emitted from the pixels PX of each pixel group PXG1 or PXG3, which travel toward the undesired path. It is possible to reduce, suppress or prevent distortion of the screen displayed to users. Furthermore, it is possible to reduce, suppress or prevent degradation of luminance of the display apparatus, thereby suppressing or preventing a reduction in luminance efficiency and reducing power consumption.

In addition, by including the first pixel group PXG1 and the third pixel group PXG3, it is possible to more efficiently perform the process, thereby reducing process cost and time.

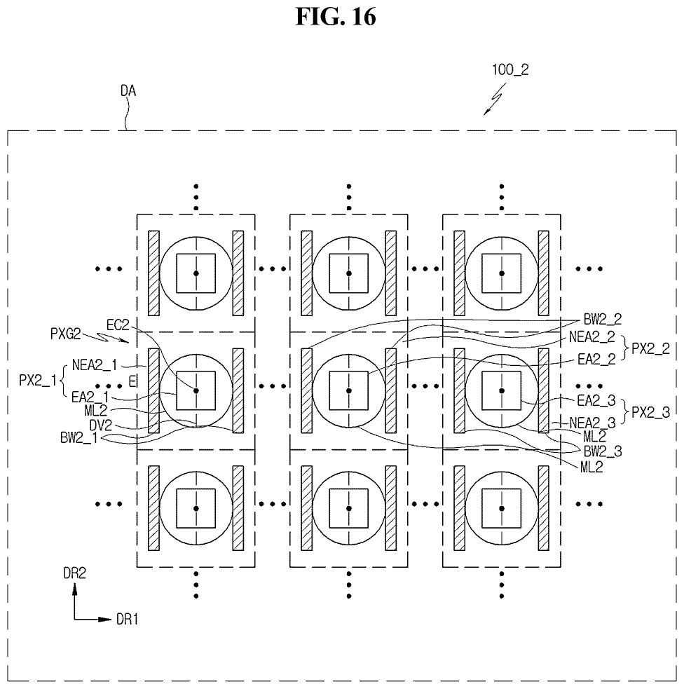

FIG. 16 is a plan view illustrating a pixel arrangement of a display panel according to still another example embodiment of the present disclosure.

Referring to FIG. 16, a display panel 100_2 according to the present embodiment can include the second pixel group PXG2 of FIG. 4, but may not include the first pixel group PXG1 and the third pixel group PXG3.

The second pixel group PXG2 can be repeatedly disposed in the second direction DR2. The second microlens ML2 and the second light-shielding member BW2 can be disposed on the pixels PX included in the second pixel group PXG2.

When the display panel 100_2 is used in a display apparatus for a vehicle, the same screen can be displayed to the driver DRIVER and the passenger CO-DRIVER.

Even in this case, since the second light-shielding member BW2 is disposed on the pixel PX, it is possible to smoothly shield and control some of the light emitted from the pixels PX of the second pixel group PXG2, which travel toward the undesired path. Accordingly, it is possible to reduce, suppress or prevent degradation of luminance of the display apparatus, thereby suppressing or preventing the reduction in luminance efficiency and reducing power consumption.

In addition, by including the second pixel group PXG2, it is possible to more efficiently perform the process, thereby reducing process cost and time.

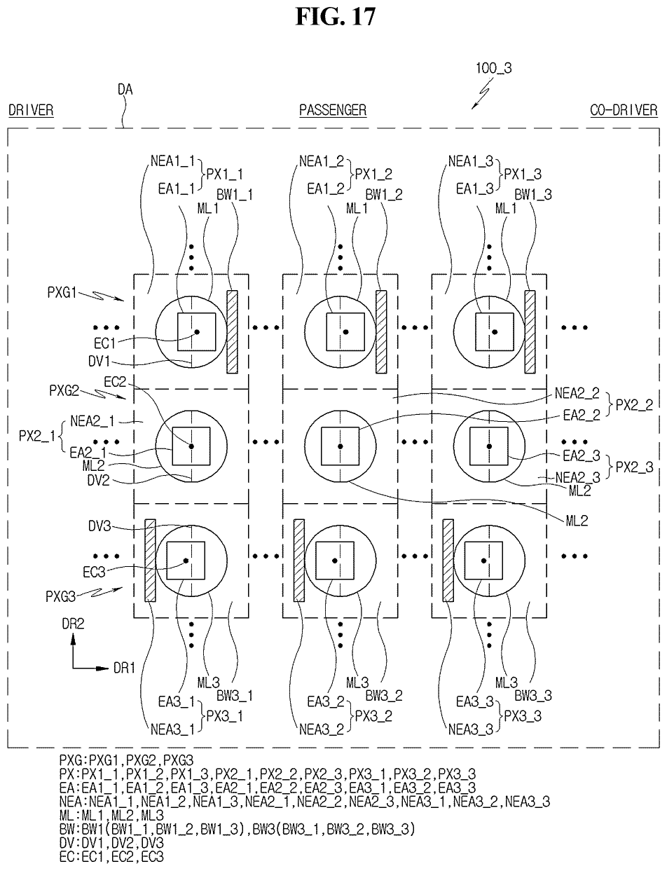

FIG. 17 is a plan view illustrating a pixel arrangement of a display panel according to still another example embodiment of the present disclosure.

Referring to FIG. 17, a display panel 100_3 according to the present embodiment can include the first pixel group PXG1, the second pixel group PXG2, and the third pixel group PXG3.

Accordingly, each pixel group PXG2 or PXG3 can display a different image and video, and the display apparatus 1 (see FIG. 1) can display two different images and videos according to a viewing angle.

The first pixel group PXG1, the second pixel group PXG2, and the third pixel group PXG3 can be alternately and repeatedly disposed in the second direction DR2. The first microlens ML1 and the first light-shielding member BW1 can be disposed on the pixels PX included in the first pixel group PXG1. The third microlens ML3 and the third light-shielding member BW3 can be disposed on the pixels PX included in the third pixel group PXG3.

However, the second microlens ML2 can be disposed on the pixels PX included in the second pixel group PXG2, and the second light-shielding member BW2 (see FIG. 4) may not be disposed thereon.

When the display panel 100_3 is used in a display apparatus for a vehicle, a screen displayed to the driver DRIVER sitting on the driver's seat, a screen displayed to the passenger CO-DRIVER sitting on the front passenger's seat, and a screen displayed to the passenger PASSENGER sitting on the rear seat can be distinctly controlled separately, and different screens can be displayed to the driver DRIVER and the passengers CO-DRIVER and PASSENGER.

Even in this case, since the light-shielding members BW1 and BW3 are disposed on the pixel PX, it is possible to smoothly shield and control some of the light emitted from the pixels PX of each pixel group PXG1 or PXG3, which travel toward the undesired path. It is possible to reduce, suppress or prevent distortion of the screen displayed to users. Furthermore, it is possible to reduce, suppress or prevent degradation of luminance of the display apparatus, thereby suppressing or preventing a reduction in luminance efficiency and reducing power consumption.

In addition, since the light-shielding member is omitted on the pixel PX of the second pixel group PXG2, it is possible to more smoothly reduce, suppress or prevent the degradation of luminance of the display apparatus.

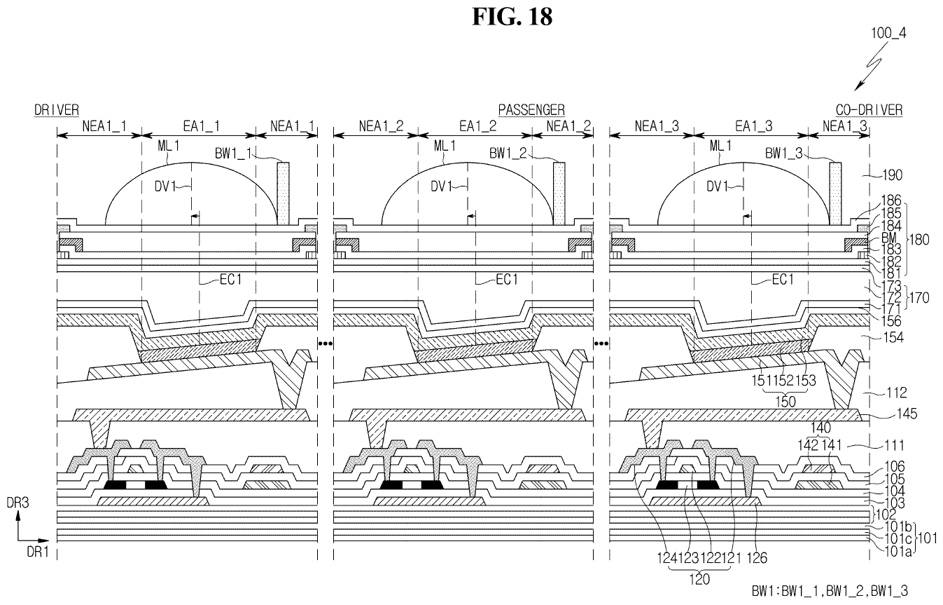

FIGS. 18 to 20 are cross-sectional views of a display panel of a display apparatus according to yet another example embodiment of the present disclosure.

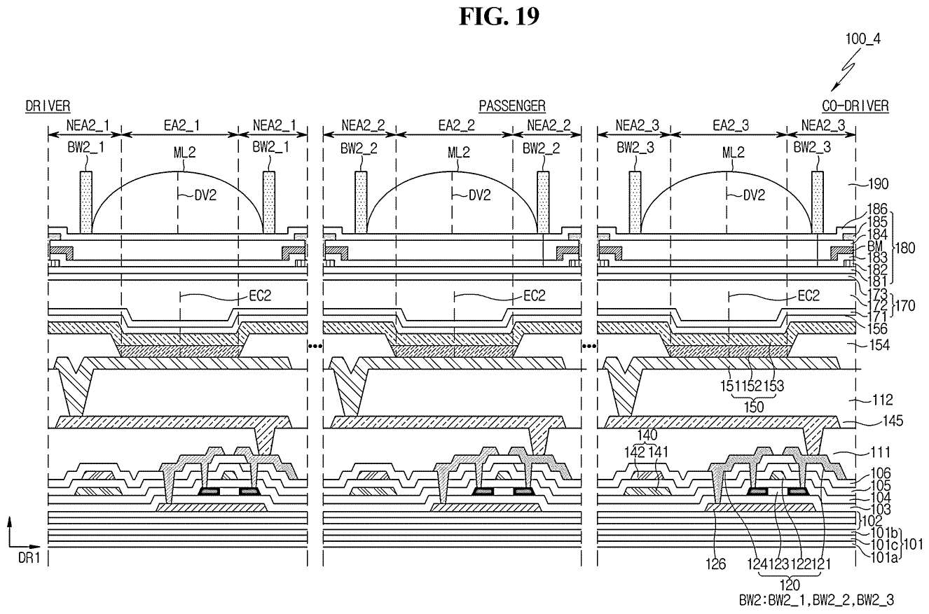

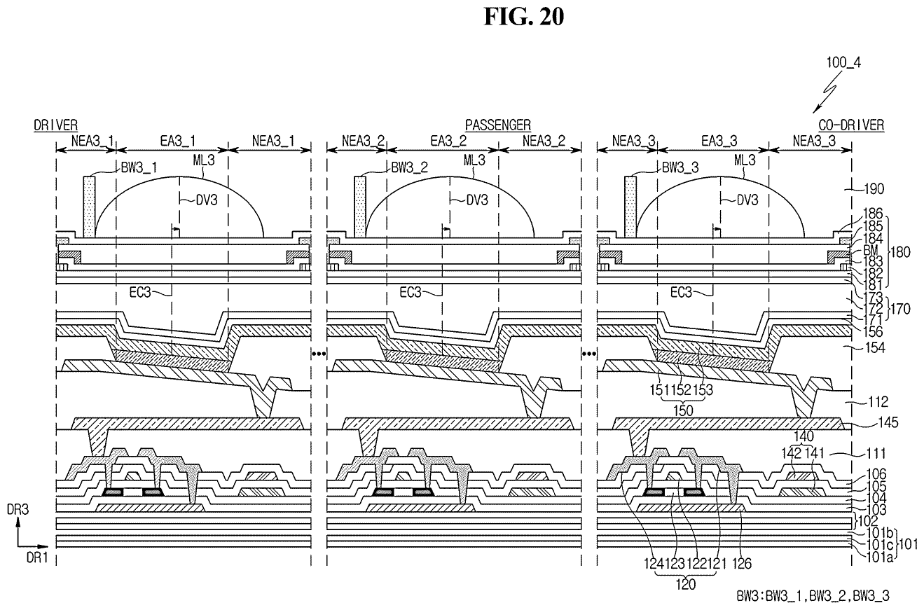

Paritulcalry, FIG. 18 illustrates a cross section of the first pixel group PXG1, FIG. 19 illustrates a cross section of the second pixel group PXG2, and FIG. 20 illustrates a cross section of the third pixel group PXG3.

Referring to FIGS. 18 to 20, the microlenses ML1, ML2, and ML3 and the light-shielding members BW1, BW2, and BW3 can be disposed on the pixels PX disposed in each pixel group PXG. The light-shielding members BW1, BW2, and BW3 disposed on the pixels PX disposed in the pixel group PXG1, PXG2, and PXG3, respectively, can all have the same height.

For example, each of the light-shielding members BW1_1, BW1_2, and BW1_3 disposed on the pixels PX of the first pixel group PXG1 can have the same height. The heights of the light-shielding members BW1_1, BW1_2, and BW1_3 can be the same as the height of the first microlens ML1, but are not limited thereto. For example, according to a design, the heights of the light-shielding members BW1_1, BW1_2, and BW1_3 can be higher or lower than the height of the first microlens ML1.

Each of the light-shielding members BW2_1, BW2_2, and BW2_3 disposed on the pixels PX of the second pixel group PXG2 can have the same height. The heights of the light-shielding members BW2_1, BW2_2, and BW2_3 can be the same as the height of the second microlens ML2, but are not limited thereto. For example, according to a design, the heights of the light-shielding members BW2_1, BW2_2, and BW2_3 can be higher or lower than the height of the second microlens ML2.

Each of the light-shielding members BW3_1, BW3_2, and BW3_3 disposed on the pixels PX of the third pixel group PXG3 can have the same height. The heights of the light-shielding members BW3_1, BW3_2, and BW3_3 can be the same as the height of the third microlens ML3, but are not limited thereto. For example, according to a design, the heights of the light-shielding members BW3_1, BW3_2, and BW3_3 can be higher or lower than the height of the third microlens ML3.

In addition, the light-shielding members BW1, BW2, and BW3 disposed on the pixels PX disposed in the pixel group PXG1, PXG2, and PXG3, respectively, can all have the same height.

For example, the light-shielding members BW1_1, BW1_2, and BW1_3 disposed on the pixels PX of the first pixel group PXG1, the light-shielding members BW2_1, BW2_2, and BW2_3 disposed on the pixels PX of the second pixel group PXG2, and the light-shielding members BW3_1, BW3_2, BW3_3 disposed on the pixels PX of the third pixel group PXG3 can all have the same height.

Even in this case, since the light-shielding members BW1, BW2, and BW3 are disposed on the pixel PX, it is possible to smoothly shield and control some of the light emitted from the pixels PX of each pixel group PXG1, PXG2, or PXG3, which travel toward the undesired path. It is possible to reduce, suppress or prevent distortion of the screen displayed to users. Furthermore, it is possible to reduce, suppress or prevent degradation of luminance of the display apparatus, thereby suppressing or preventing a reduction in luminance efficiency and reducing power consumption.

In addition, since each light-shielding member BW1, BW2, or BW3 is formed at the same height, it is possible to more efficiently perform the process, thereby reducing process cost and time.

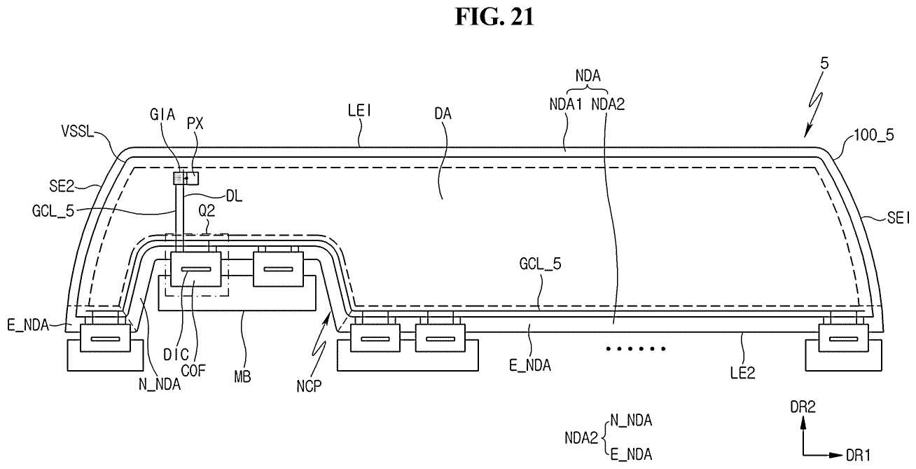

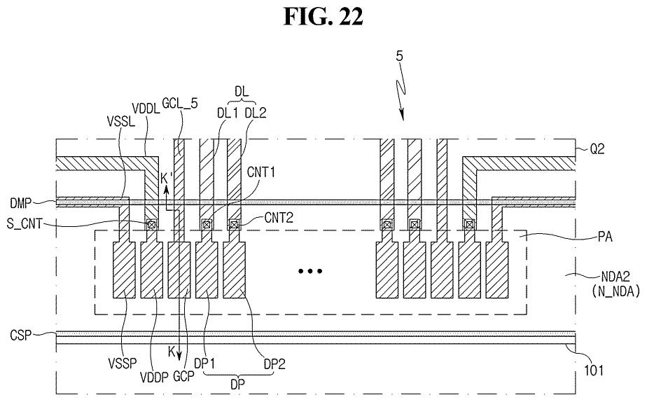

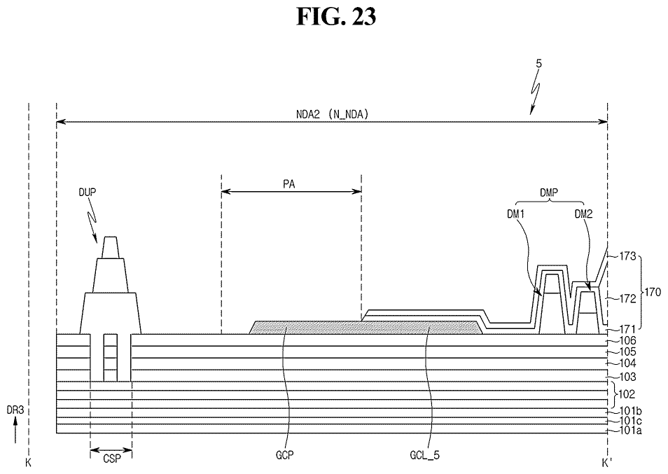

FIG. 21 is a plan view of a display apparatus according to yet another example embodiment of the present disclosure. FIG. 22 is an enlarged view of area Q2 in FIG. 21. FIG. 23 is a cross-sectional view along line K-K′ in FIG. 22.

Particularly, FIG. 22 is a view of area Q2 of a display apparatus 5 according to yet another example embodiment of the present disclosure, from which the flexible film COF, the main board MB, and the drive IC DIC are omitted.

Referring to FIGS. 21 to 23, in the display apparatus 5 according to the present embodiment, the gate driving unit GIP (see FIG. 1) may not separately be disposed in the non-display area NDA, and a pixel gate driving unit GIA can be disposed in the display area DA.

The pixel gate driving unit GIA can be provided as a plurality of pixel gate drivers, and each pixel gate driving unit GIA can be connected to each of the plurality of pixels PX. The pixel gate driving unit GIA can be disposed around the pixel PX. The pixel gate driving unit GIA can be disposed between adjacent pixels PX.

For example, the pixel gate driving unit GIA can be disposed between adjacent pixels PX in the first direction DR1. The pixel PX and the pixel gate driving unit GIA can be alternately repeatedly disposed in the first direction DR1. The pixel PX can be continuously repeatedly disposed in the second direction DR2. The pixel gate driving unit GIA can be continuously repeatedly disposed in the second direction DR2.

The pixel gate driving unit GIA can perform substantially the same role as the gate driving unit GIP (see FIG. 1). The pixel gate driving unit GIA can include at least one transistor.

The pixel gate driving unit GIA can be electrically connected to an adjacent pixel PX.

The pixel gate driving unit GIA can receive a gate control signal from the drive IC DIC through a gate control line GCL_5. The pixel gate driving unit GIA can generate a scan signal and a light-emitting signal (or a light-emitting control signal) based on the gate control signal. Accordingly, the driving of the adjacent pixel PX can be controlled.

Since the pixel gate driving unit GIA is disposed in the display area DA, it is possible to minimize the non-display area NDA or the bezel area, thereby providing improved aesthetic feeling to a user.

The display apparatus 5 can further include the gate control line GCL_5 and a gate control pad GCP.

The gate control line GCL_5 can be disposed in the non-display area NDA and the display area DA. The gate control line GCL_5 can be disposed in the second non-display area NDA2, but is not limited thereto. The gate control line GCL_5 can be disposed in an extension direction of the second non-display area NDA2.

The gate control line GCL_5 can be partially disposed in the second non-display area NDA2 and can extend from the second non-display area NDA2 to the pixel gate driving unit GIA of the display area DA. The gate control line GCL_5 can be electrically connected to the plurality of pixel gate driving units GIAs disposed in the display area DA.

The gate control pad GCP can be disposed in the pad area PA. In the pad area PA, the gate control pad GCP is illustrated as being disposed between the high-potential voltage pad VDDP and the data pad DP, but is not limited thereto, and the arrangement location of the gate control pad GCP can vary according to a design.

The gate control pad GCP can include the same material as the gate control line GCL_5, but is not limited thereto. The gate control pad GCP and the gate control line GCL_5 can be formed integrally, but are not limited thereto.

The gate control pad GCP and the gate control line GCL_5 can be disposed on the fourth insulating layer 106. The gate control pad GCP and the gate control line GCL_5 can be disposed on the same layer as the source electrode 121 (see FIG. 5) and the drain electrode 124 (see FIG. 5) and can include the same material as the source electrode 121 and the drain electrode 124, and the gate control pad GCP, the gate control line GCL, the source electrode 121, and the drain electrode 124 can be formed together using one mask by the same process, but the embodiments of the present disclosure are not limited thereto.

The plurality of pads VSSP, VDDP, DP, and GCP may not be covered by the plurality of inorganic films. The plurality of inorganic films disposed on the fourth insulating layer 106 can expose the plurality of pads VSSP, VDDP, DP, and GCP. The plurality of inorganic films disposed on the fourth insulating layer 106 may not be disposed in the pad area PA.

For example, the first inorganic encapsulation layer 171, the second inorganic encapsulation layer 173, the touch buffer layer 181, the first touch insulating layer 183, and the third touch insulating layer 186 can be disposed up to the end of the substrate 101 in the notch non-display area N_NDA, but may not be disposed in the pad area PA. Accordingly, the plurality of pads VSSP, VDDP, DP, and GCP disposed on the fourth insulating layer 106 can be exposed, and the display panel 100_5 can be adhered and electrically connected to the flexible film COF.

Since the gate driving unit GIP (see FIG. 1) is omitted from the non-display area NDA and the pixel gate driving unit GIA is disposed in the display area DA, the non-display area NDA can be reduced, thereby reducing the bezel area and increasing the display area DA.

Even in this case, since the light-shielding members BW1, BW2, and BW3 are disposed on the pixels PX, it is possible to smoothly shield and control some of the light emitted from the pixels PX of each pixel group PXG1, PXG2, or PXG3, which travel toward the undesired path. It is possible to reduce, suppress or prevent distortion of the screen displayed to users. Furthermore, it is possible to reduce, suppress or prevent degradation of luminance of the display apparatus, thereby suppressing or preventing a reduction in luminance efficiency and reducing power consumption.

A display apparatus according to various example embodiments of the present disclosure can be described as follows.

According to embodiments of the present disclosure, there is provided a display apparatus including a first pixel group including a plurality of pixels, a first microlens corresponding to each of the plurality of pixels of the first pixel group, and a first light-shielding member corresponding to each of the plurality of pixels of the first pixel group, in which the first light-shielding member is disposed at at least one of one side (e.g., first side) and the other side (e.g., second side) of the first microlens in a first direction.

According to various example embodiments of the present disclosure, the first light-shielding member can be disposed at one side of the first microlens in the first direction, the pixels of the first pixel group can be disposed in the first direction, and the first light-shielding member can have a height that increases toward a pixel disposed at the one side in the first direction.

According to various example embodiments of the present disclosure, the display apparatus can further include a third pixel group including a plurality of pixels, a third microlens corresponding to each of the plurality of pixels of the third pixel group, and a third light-shielding member corresponding to each of the plurality of pixels of the third pixel group, in which the third light-shielding member can be disposed at the other side (e.g., second side) of the third microlens in the first direction.

According to various example embodiments of the present disclosure, the pixels of the third pixel group can be disposed in the first direction, and the third light-shielding member can have a height that increases toward a pixel disposed at the other side in the first direction.

According to various example embodiments of the present disclosure, the first pixel group and the third pixel group can be alternately and repeatedly disposed in a second direction intersecting the first direction.

The display apparatus can further include a second pixel group including a plurality of pixels, and a second microlens corresponding to each of the plurality of pixels of the second pixel group.

According to various example embodiments of the present disclosure, the display apparatus can further include a second light-shielding member corresponding to each of the plurality of pixels of the second pixel group, in which the second light-shielding member can be disposed at both one side (e.g., first side) and the other side (e.g., second side) of the second microlens in the first direction, and the second light-shielding member can have a height that increases toward pixels disposed at the one side and the other side in the first direction.

According to various example embodiments of the present disclosure, the first pixel group, the second pixel group, and the third pixel group can be alternately and repeatedly disposed in the second direction intersecting the first direction.

According to various example embodiments of the present disclosure, the first light-shielding member can be disposed at both one side and the other side of the first microlens in the first direction, and the first pixel group can be repeatedly disposed in the second direction intersecting the first direction.

According to various example embodiments of the present disclosure, the display apparatus can further include a second pixel group including a plurality of pixels, a second microlens corresponding to each of the plurality of pixels of the second pixel group, a second light-shielding member corresponding to each of the plurality of pixels of the second pixel group, a third pixel group including a plurality of pixels, a third microlens corresponding to each of the plurality of pixels of the third pixel group, and a third light-shielding member corresponding to each of the plurality of pixels of the third pixel group, in which the second light-shielding member can be disposed at one side of the second microlens in the first direction, the third light-shielding member can be disposed at the other side of the third microlens in the first direction, and the first pixel group, the second pixel group, and the third pixel group can be alternately and repeatedly disposed in the second direction.

According to various example embodiments of the present disclosure, the first light-shielding member, the second light-shielding member, and the third light-shielding member can all have the same height.

According to various example embodiments of the present disclosure, the display apparatus can further include a display area in which the first pixel group is disposed, and a non-display area around the display area, in which the first light-shielding member can be disposed in the display area.

According to various example embodiments of the present disclosure, the first light-shielding member can have a height that increases toward the pixels disposed at the one side and the other side in the first direction.

According to various example embodiments of the present disclosure, the first light-shielding member can be formed in a black-based color.

According to various example embodiments of the present disclosure, the first light-shielding member can come into direct contact with the first microlens.

According to various example embodiments of the present disclosure, the display apparatus can further include a lens protective layer disposed on the first microlens and the first light-shielding member, in which the lens protective layer can come into direct contact with the first microlens and the first light-shielding member.

According to example embodiments of the present disclosure, there is provided a display apparatus including a first pixel group including a plurality of pixels, a third pixel group including a plurality of pixels, a first microlens corresponding to each of the plurality of pixels of the first pixel group, a third microlens corresponding to each of the plurality of pixels of the third pixel group, a first light-shielding member corresponding to each of the plurality of pixels of the first pixel group, and a third light-shielding member corresponding to each of the plurality of pixels of the third pixel group, in which the first light-shielding member is disposed at one side of the first microlens in a first direction, and the third light-shielding member is disposed at the other side of the third microlens in the first direction.

According to various example embodiments of the present disclosure, the display apparatus can further include a second pixel group including a plurality of pixels, a second microlens corresponding to each of the plurality of pixels of the second pixel group, and a second light-shielding member corresponding to each of the plurality of pixels of the second pixel group, in which the second light-shielding member can be disposed at one side and the other side of the second microlens in the first direction.

According to various example embodiments of the present disclosure, the first pixel group, the second pixel group, and the third pixel group can be alternately and repeatedly disposed in the second direction intersecting the first direction.

According to various example embodiments of the present disclosure, the first light-shielding member can have a height that increases toward the pixel disposed at the one side in the first direction, and the third light-shielding member can have a height that increases toward the pixel disposed at the other side in the first direction.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
100: display apparatus
101: substrate
NCP: Notch
DA: display area
NDA: non-display area
NDA1: first non-display area
NDA2: second non-display area
N_NDA: notch non-display area
E_NDA: extension non-display area
PA: pad area
PX: pixel
PX: pixel
EA: light-emitting area
NEA: non-light-emitting area
ML: microlens
BW: light-shielding member
DV: division line
EC: center
150: light emitting part
170: encapsulation part

What is claimed is:

1. A display apparatus comprising:
a first pixel group including a plurality of pixels;
a first microlens corresponding to each of the plurality of pixels of the first pixel group; and
a first light-shielding member corresponding to each of the plurality of pixels of the first pixel group,
wherein the first light-shielding member is disposed at at least one of a first side and a second side of the first microlens in a first direction.

2. The display apparatus of claim 1, wherein the first light-shielding member is disposed at the first side of the first microlens in the first direction,
the plurality of pixels of the first pixel group are arranged in the first direction, and
the first light-shielding member has a height that increases toward the pixel disposed at the first side in the first direction.

3. The display apparatus of claim 2, further comprising:
a third pixel group including a plurality of pixels;
a third microlens corresponding to each of the plurality of pixels of the third pixel group; and
a third light-shielding member corresponding to each of the plurality of pixels of the third pixel group,
wherein the third light-shielding member is disposed at a second side of the third microlens in the first direction.

4. The display apparatus of claim 3, wherein the plurality of pixels of the third pixel group are arranged in the first direction, and
the third light-shielding member has a height that increases toward the pixel disposed at the second side of the third microlens in the first direction.

5. The display apparatus of claim 4, wherein the first pixel group and the third pixel group are alternately and repeatedly disposed in a second direction intersecting the first direction.

6. The display apparatus of claim 4, further comprising:
a second pixel group including a plurality of pixels; and
a second microlens corresponding to each of the plurality of pixels of the second pixel group.

7. The display apparatus of claim 6, further comprising a second light-shielding member corresponding to each of the plurality of pixels of the second pixel group,
wherein the second light-shielding member is disposed at a first side and a second side of the second microlens in the first direction, and
the second light-shielding member has a height that increases from a center portion of the second pixel group toward pixels disposed at the first side and the second side of the second microlens in the first direction.

8. The display apparatus of claim 7, wherein the first pixel group, the second pixel group, and the third pixel group are alternately and repeatedly disposed in a second direction intersecting the first direction.

9. The display apparatus of claim 1, wherein the first light-shielding member is disposed at the first side and the second side of the first microlens in the first direction, and
the first pixel group is repeatedly disposed in a second direction intersecting the first direction.

10. The display apparatus of claim 9, further comprising:
a second pixel group including a plurality of pixels;
a second microlens corresponding to each of the plurality of pixels of the second pixel group;
a second light-shielding member corresponding to each of the plurality of pixels of the second pixel group;
a third pixel group including a plurality of pixels;
a third microlens corresponding to each of the plurality of pixels of the third pixel group; and
a third light-shielding member corresponding to each of the plurality of pixels of the third pixel group,
wherein the second light-shielding member is disposed at a first side of the second microlens in the first direction,
the third light-shielding member is disposed at a second side of the third microlens in the first direction, and
the first pixel group, the second pixel group, and the third pixel group are alternately and repeatedly disposed in the second direction.

11. The display apparatus of claim 10, wherein all of the first light-shielding member, the second light-shielding member, and the third light-shielding member have a same height.

12. The display apparatus of claim 1, further comprising:
a display area in which the first pixel group is disposed; and
a non-display area adjacent to the display area,
wherein the first light-shielding member is disposed in the display area.

13. The display apparatus of claim 9, wherein the first light-shielding member has a height that increases from a center portion of the first pixel group toward pixels disposed at the first side and the second side of the first microlens in the first direction.

14. The display apparatus of claim 1, wherein the first light-shielding member includes a black-based color.

15. The display apparatus of claim 1, wherein the first light-shielding member comes into direct contact with the first microlens or is disposed to be spaced apart from the first microlens.

16. The display apparatus of claim 1, further comprising a lens protective layer disposed on the first microlens and the first light-shielding member,
wherein the lens protective layer comes into direct contact with the first microlens and the first light-shielding member.

17. The display apparatus of claim 16, wherein a refractive index of the lens protective layer is smaller than a refractive index of the first microlens.

18. The display apparatus of claim 1, wherein the plurality of pixels of the first pixel group are arranged in the first direction.

19. The display apparatus of claim 1, further comprising a notch formed at one edge of the display apparatus.

20. The display apparatus of claim 1, wherein a length of the first light-shielding member in a second direction intersecting the first direction is equal to or greater than a diameter of the first microlens.

21. The display apparatus of claim 1, wherein the first light-shielding member is disposed at the first side of the first microlens in the first direction, and
wherein a center of a light-emitting area of the pixel of the first pixel group is misaligned with a center of the first microlens.

22. A display apparatus comprising:
a first pixel group including a plurality of pixels;
a third pixel group including a plurality of pixels;
a first microlens corresponding to each of the plurality of pixels of the first pixel group;
a third microlens corresponding to each of the plurality of pixels of the third pixel group;
a first light-shielding member corresponding to each of the plurality of pixels of the first pixel group; and
a third light-shielding member corresponding to each of the plurality of pixels of the third pixel group,
wherein the first light-shielding member is disposed at a first side of the first microlens in a first direction, and
the third light-shielding member is disposed at a second side of the third microlens in the first direction.

23. The display apparatus of claim 22, further comprising:
a second pixel group including a plurality of pixels;
a second microlens corresponding to each of the plurality of pixels of the second pixel group; and
a second light-shielding member corresponding to each of the plurality of pixels of the second pixel group,
wherein the second light-shielding member is disposed at a first side and a second side of the second microlens in the first direction.

24. The display apparatus of claim 23, wherein the first pixel group, the second pixel group, and the third pixel group are alternately and repeatedly disposed in a second direction intersecting the first direction.

25. The display apparatus of claim 22, wherein the first light-shielding member has a height that increases toward a pixel disposed at the first side of the first microlens in the first direction, and
the third light-shielding member has a height that increases toward a pixel disposed at second side of the third microlens in the first direction.

26. The display apparatus of claim 22, wherein the first pixel group and the third pixel group are configured to display a different image and video.

27. A vehicle, comprising the display apparatus of claim 1.

28. The vehicle of claim 27, wherein the display apparatus is disposed across a driver's seat and a front passenger's seat arranged in the first direction.

29. The vehicle of claim 28, wherein the display apparatus is configured to provide different images to the driver's seat and the front passenger's seat.
